(19) United States
(12) Patent Application Publication
(10) Pub. No.: US 2024/0071879 A1
(43) Pub. Date: Feb. 29, 2024

(54) SEMICONDUCTOR DEVICE

(71) Applicant: ROHM CO., LTD., Kyoto-shi (JP)

(72) Inventors: Tianyu WANG, Kyoto-shi (JP); Xian WANG, Kyoto-shi (JP)

(21) Appl. No.: 18/500,653

(22) Filed: Nov. 2, 2023

Related U.S. Application Data
(63) Continuation of application No. PCT/CN2021/093006, filed on May 11, 2021.

(51) Int. Cl. H01L 23/495; H01L 23/00; H01L 23/31

(52) U.S. Cl. CPC H01L 23/49575; H01L 23/3114; H01L 23/49562; H01L 24/48; H01L 2224/48137; H01L 2224/48245

(57) ABSTRACT

The present disclosure provides a semiconductor device, including an encapsulation body, a first transistor and a second transistor. The first transistor includes a control electrode, a first terminal and a second terminal, and the first transistor is configured to allow a current to flow from the first terminal to the second terminal under the control of a potential at the control electrode of the first transistor. A first electrode of the second transistor is electrically coupled to the control electrode of the first transistor, and a second electrode of the second transistor is electrically coupled to the second terminal of the first transistor. The first transistor and the second transistor are encapsulated by the same encapsulation body, the control electrode of the first transistor is electrically coupled to a first control electrode pin, and the control electrode of the second transistor is electrically coupled to a second control electrode pin. According to the present disclosure, it is able to ensure a better clamping effect and simplify the wiring.

### TECHNICAL FIELD

The present disclosure relates to a semiconductor device.

### BACKGROUND

In the related art, usually a control electrode of a first transistor for switching is provided with a clamping element (e.g., a clamping transistor or capacitor). However, in actual use, the clamping element is generally arranged in a Printed Circuit Board (PCB) card.

A heat dissipater needs to be provided, so there is a large distance between a pin of the first transistor and the PCB card. At this time, it is impossible to provide a small distance between a wafer for the first transistor and the clamping element, and thereby an effect of the clamping element is degraded significantly.

### BRIEF DESCRIPTION OF THE DRAWINGS

FIG. 1 is a schematic view showing a connection relationship between a first transistor and a second transistor of a semiconductor device according to at least one embodiment of the present disclosure;

FIG. 2 is a schematic view showing the semiconductor device according to at least one embodiment of the present disclosure;

FIG. 3 is another schematic view showing the semiconductor device according to at least one embodiment of the present disclosure;

FIG. 4 is a sectional view of the semiconductor device along line A-A′ in FIG. 3;

FIG. 5 is yet another schematic view showing the semiconductor device according to at least one embodiment of the present disclosure;

FIG. 6 is still yet another schematic view showing the semiconductor device according to at least one embodiment of the present disclosure;

FIG. 7 is still yet another schematic view showing the semiconductor device according to at least one embodiment of the present disclosure;

FIG. 8 is still yet another schematic view showing the semiconductor device according to at least one embodiment of the present disclosure;

FIG. 9 is still yet another schematic view showing the semiconductor device according to at least one embodiment of the present disclosure;

FIG. 10 is a schematic view showing a connection relationship between the first transistor and a capacitor of the semiconductor device according to at least one embodiment of the present disclosure;

FIG. 11 is still yet another schematic view showing the semiconductor device according to at least one embodiment of the present disclosure; and

FIG. 12 is a schematic view showing a switching system including a semiconductor chip according to at least one embodiment of the present disclosure.

### DETAILED DESCRIPTION OF EMBODIMENTS

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

All transistors adopted in the embodiments of the present disclosure may be triodes, thin film transistors (TFT), field effect transistors (FETs) or any other elements having an identical characteristic. In order to differentiate two electrodes other than a control electrode from each other, one of the two electrodes is called as first electrode and the other is called as second electrode.

In actual use, when the transistor is a triode, the control electrode may be a base, the first electrode may be a collector and the second electrode may be an emitter, or the control electrode may be a base, the first electrode may be an emitter and the second electrode may be a collector.

In actual use, when the transistor is a TFT or FET, the control electrode may be a gate electrode, the first electrode may be a drain electrode and the second electrode may be a source electrode, or the control electrode may be a gate electrode, the first electrode may be a source electrode and the second electrode may be a drain electrode.

The present disclosure provides in some embodiments a semiconductor device, which includes an encapsulation body, a first transistor and a second transistor. The first transistor includes a control electrode, a first terminal and a second terminal; the first transistor is configured to allow a current to flow from the first terminal to the second terminal under the control of a potential at the control electrode of the first transistor; a first electrode of the second transistor is electrically coupled to the control electrode of the first transistor, and a second electrode of the second transistor is electrically coupled to the second terminal of the first transistor; and the first transistor and the second transistor are encapsulated by the same encapsulation body, the control electrode of the first transistor is electrically coupled to a first control electrode pin, and a control electrode of the second transistor is electrically coupled to a second control electrode pin.

In at least one embodiment of the present disclosure, the control electrode of the first transistor is electrically coupled to the first control electrode pin through a binding line, and the control electrode of the second transistor is electrically coupled to the second control electrode pin through a binding line. A voltage signal is applied to the second control electrode pin, which results in an interference signal on a circuit being relatively small. The binding line is a lead.

According to the semiconductor device in the embodiments of the present disclosure, the first transistor and the second transistor (the second transistor is a Miller clamping transistor) are encapsulated by the same encapsulation body, so as to reduce a distance between the control electrode of the second transistor and the control electrode of the first transistor, thereby to ensure a better clamping effect and simplify the wiring.

During the implementation, at least a part of the first control electrode pin is, but not limited to, arranged outside the encapsulation body, and at least a part of the second control electrode pin is, but not limited to, arranged outside the encapsulation body.

During the implementation, the encapsulation body is made of, but not limited to, resin.

In some possible embodiments of the present disclosure, the first transistor is an N-type transistor, the first terminal is a first electrode, the first electrode is a drain electrode, the second terminal is a second electrode, and the second electrode is a source electrode; or the first transistor is a P-type transistor, the first terminal is a first electrode, the first electrode is a source electrode, the second terminal is a second electrode, and the second electrode is a drain electrode.

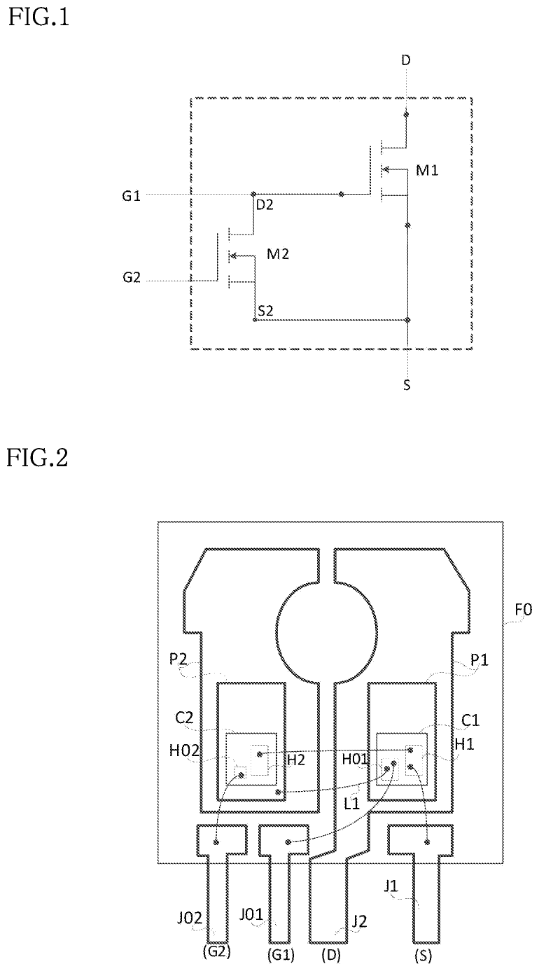

As shown in FIG. 1, the semiconductor device in the embodiments of the present disclosure includes a first transistor M1 and a second transistor M2. The first transistor M1 is configured to allow a current to flow from a drain electrode D of the first transistor D1 to a source electrode S of the first transistor M1 under the control of a potential at a gate electrode G1 of the first transistor M1. A drain electrode D2 of the second transistor M2 is electrically coupled to the gate electrode G1 of the first transistor M1, and a source electrode S2 of the second transistor M2 is electrically coupled to the source electrode S of the first transistor M1.

In FIGS. 1, M1 and M2 are, but not limited to, N-type MOSFETs.

In some possible embodiments of the present disclosure, the semiconductor device further includes a first chip support member, a second chip support member, a first semiconductor chip, a second semiconductor chip, a first control electrode pin and a second control electrode pin; the first chip support member is insulated from the second chip support member; the first transistor is formed on the first semiconductor chip, and the second transistor is formed on the second semiconductor chip; at least a part of the first chip support member, at least a part of the second chip support member, the first semiconductor chip and the second semiconductor chip are encapsulated by the same encapsulation body; the first semiconductor chip is provided with a first surface and a first back surface opposite to the first surface, and the second semiconductor chip is provided with a second surface and a second back surface opposite to the second surface; a first control electrode pad and a first pad are formed on the first surface of the first semiconductor chip, and the first back surface is electrically coupled to the first terminal of the first transistor; the first control electrode pad is electrically coupled to the control electrode of the first transistor and the first control electrode pad respectively, and the first pad is electrically coupled to the second terminal of the first transistor; a second control electrode pad and a second pad are formed on the first surface of the second semiconductor chip, and the second back surface is electrically coupled to the first electrode of the second transistor; the second control electrode pad is electrically coupled to the control electrode of the second transistor and the second control electrode pin respectively, and the second electrode of the second transistor is electrically coupled to the second pad; the first chip support member is provided with a first upper surface, the first semiconductor chip is supported on the first upper surface of the first chip support member, and the first back surface of the first semiconductor chip faces the first upper surface and is electrically coupled to the first chip support member; and the second chip support member is provided with a second upper surface, the second semiconductor chip is supported on the second upper surface of the second chip support member, and the second back surface of the second semiconductor chip faces the second upper surface and is electrically coupled to the second chip support member.

In actual use, the semiconductor device in the embodiments of the present disclosure includes two chip support members and two semiconductor chips. The first transistor is formed on the first semiconductor chip, and the second transistor is formed on the second semiconductor chip. At least a part of the first chip support member, at least a part of the second chip support member, the first semiconductor chip and the second semiconductor chip are encapsulated by the same encapsulation body. The first transistor is, but not limited to, an MOSFET made of SiC, and the second transistor is, but not limited to, an MOSFET made of Si.

In some possible embodiments of the present disclosure, the second chip support member is electrically coupled to the first control electrode pad through a lead, so that the first electrode of the second transistor is electrically coupled to the control electrode of the first transistor. The second pad is electrically coupled to the first pad, so that the second electrode of the second transistor is electrically coupled to the second terminal of the first transistor. The lead between the second chip support member and the first control electrode pad is short.

In some possible embodiments of the present disclosure, the second chip support member is electrically coupled to the first control electrode pin through a lead, so as to prevent an internal space of a wafer from being occupied, and enable the first electrode of the second transistor to be electrically coupled to the control electrode of the first transistor. The second pad is electrically coupled to the first pad, so that the second electrode of the second transistor is electrically coupled to the second terminal of the first transistor. The lead between the second chip support member and the first control electrode pin is short.

During the implementation, the semiconductor device further includes a first electrode pin and a second electrode pin. The first electrode pin is electrically coupled to the first pad, so that the first electrode pin is electrically coupled to the second terminal of the first transistor. The second electrode pin is electrically coupled to the first chip support member, so that the second electrode pin is electrically coupled to the first terminal of the first transistor.

In actual use, at least a part of the first electrode pin is, but not limited to, arranged outside the encapsulation body, and at least a part of the second electrode pin is, but not limited to, arranged outside the encapsulation body.

As shown in FIG. 2, the semiconductor device in the embodiments of the present disclosure includes a first transistor, a second transistor, an encapsulation body F0, a first chi support member P1, a second chip support member P2, a first semiconductor chip C1, a second semiconductor chip C2, a first control electrode pin J01, a second control electrode pin J02, a first electrode pin J1 and a second electrode pin J2. The first chip support member P1 is insulated from the second chip support member P2. The first transistor is formed on the first semiconductor chip C1, and the second transistor is formed on the second semiconductor chip C2. The first chip support member P1, the second chip support member P2, the first semiconductor chip C1 and the second semiconductor chip C2 are encapsulated by the encapsulation body F0. The first semiconductor chip C1 is provided with a first surface and a first back surface opposite to the first surface, and the second semiconductor chip C2 is provided with a second surface and a second back surface opposite to the second surface. A first control electrode pad H01 and a first pad H1 are formed on the first surface of the first semiconductor chip C1, the first back surface is electrically coupled to the first terminal of the first transistor. The first control electrode pad H01 is electrically coupled to a control electrode of the first transistor and the first control electrode pin J01 respectively, and the first pad H1 is electrically coupled to a second terminal of the first transistor. A second control electrode pad H02 and a second pad H2 are formed on the second surface of the semiconductor chip C2, and the second back surface is electrically coupled to a first electrode of the second transistor. The second control electrode pad H02 is electrically coupled to a control electrode of the second transistor and the second control electrode pin J02, and a second electrode of the second transistor is electrically coupled to the second pad H2. The first chip support member P1 is provided with a first upper surface, the first semiconductor chip C1 is supported on the first upper surface of the first chip support member P1, and the first back surface of the first semiconductor chip C1 faces the first upper surface. The first back surface of the first semiconductor chip C1 is electrically coupled to the first chip support member P1, so that the first chip support member P1 is electrically coupled to the first terminal of the first transistor. The second chip support member P2 is provided with a second upper surface, the second semiconductor chip C2 is supported on the second upper surface of the second chip support member P2, and the second back surface of the second semiconductor chip C2 faces the second upper surface. The second back surface of the second semiconductor chip C2 is electrically coupled to the second chip support member P2, so that the second chip support member P2 is electrically coupled to the first electrode of the second transistor. The second chip support member P2 is electrically coupled to the first control electrode pad H01 through a first lead L1, so that the first electrode of the second transistor is electrically coupled to a control electrode of the first transistor. The first control electrode pad H01 is arranged closer to the second chip support member P2, so as to shorten the first lead L1, thereby to ensure a better clamping effect and simplify the wiring. The second pad H2 is electrically coupled to the first pad H1, so that the second terminal of the first transistor is electrically coupled to the second electrode of the second transistor. The first electrode pin J1 is electrically coupled to the first pad H1, so that the first electrode pin J1 is electrically coupled to the second terminal of the first transistor. The second electrode pin J2 is electrically coupled to the first chip support member P1, so that the second electrode pin J2 is electrically coupled to the first terminal of the first transistor.

In FIG. 2, the control electrode of the first transistor is a gate electrode, the first terminal of the first transistor is a drain electrode, the second terminal of the first transistor is a source electrode, the control electrode of the second transistor is a gate electrode, the first electrode of the second transistor is a drain electrode and the second electrode of the second transistor is a source electrode, but the present disclosure is not limited thereto. In FIG. 2, the first transistor is an MOSFET made of SiC, and the second transistor is an MOSFET made of Si. The first chip support member P1 is arranged at a right side of the second chip support member P2, but the present disclosure is not limited thereto. In actual use, P1 may also be arranged at a left side of P2.

In addition, during the manufacture of a SiC MOSFET wafer, the second transistor (the second transistor is a Miller clamping transistor) may also be arranged in a very small area, so as to integrate the Miller clamping transistor into the SiC MOSFET.

In FIG. 2, a metal plate arranged at a right side forms the first chip support member P1, and a metal plate arranged at a left side forms the second chip support member P2. The first chip support member P1 is linked to the second electrode pin J2 so as to be formed integrally, and the first chip support member P1 is electrically coupled to the second electrode pin J2. The first control electrode pin J01 and the first electrode pin J1 are arranged in such a manner as to be separated from each other through the second electrode pin J2. To be specific, as shown in FIG. 2, J1 is arranged at a right side of J2, J01 is arranged at a left side of J2, J02 is arranged at a left side of J01, and J02, J01, J2 and J1 are insulated from each other.

In FIG. 2, P1 is arranged at a right side of P2, and J02, J01, J2 and J1 are arranged sequentially from left to right, so as to enable the second control electrode pad H02 on P2 to be arranged closer to J02, enable the first control electrode pad H01 on P1 to be arranged closer to J01, and enable the first pad H1 on P1 to be arranged closer to J1, thereby to facilitate the connection between H02 and J02, the connection between H01 and J01, and the connection between H1 and J1.

In FIG. 2, the first semiconductor chip C1 is supported on the first chip support member P1 through, e.g., a conductive adhesive material made of a silver solder or a tin solder paste, the MOSFET made of SiC is formed on the first semiconductor chip C1, the first back surface of the first semiconductor chip C1 is formed into a drain electrode, and the first control electrode pad H01 and the first pad H1 are formed on the first surface of the first semiconductor chip C1. In other words, the drain electrode of the first transistor is formed on the first back surface of the first semiconductor chip C1, and the first control electrode pad H01 electrically coupled to the gate electrode of the first transistor and the first pad H1 electrically coupled to the source electrode of the first transistor are arranged on the first surface of the first semiconductor chip C1.

In FIG. 2, the second semiconductor chip C2 is supported on the second chip support member P2 through, e.g., a conductive adhesive material made of a silver solder or a tin solder paste, the MOSFET made of Si is formed on the second semiconductor chip C2, the second back surface of the second semiconductor chip C2 is formed into a drain electrode, and the second control electrode pad H02 and the second pad H2 are formed on the first surface of the second semiconductor chip C2. In other words, the drain electrode of the second transistor is formed on the second back surface of the second semiconductor chip C2, and the second control electrode pad H02 electrically coupled to the gate electrode of the second transistor and the second pad H2 electrically coupled to the source electrode of the second transistor are arranged on the first surface of the second semiconductor chip C2.

In FIG. 2, the first semiconductor chip C1 is supported on the first chip support member P1 through the conductive adhesive material, so the drain electrode of the first transistor on the back surface of the first semiconductor chip C1 is electrically coupled to the first chip support member P1. The second semiconductor chip C2 is supported on the second chip support member P2 through the conductive adhesive material, so the drain electrode of the second transistor on the back surface of the second semiconductor chip C2 is electrically coupled to the second chip support member P2.

In FIG. 2, the first chip support member P1, the second chip support member P2, the first semiconductor chip C1, the second semiconductor chip C2, a part of J02, a part of J01, a part of J2 and a part of J1 are encapsulated by the encapsulation body F0.

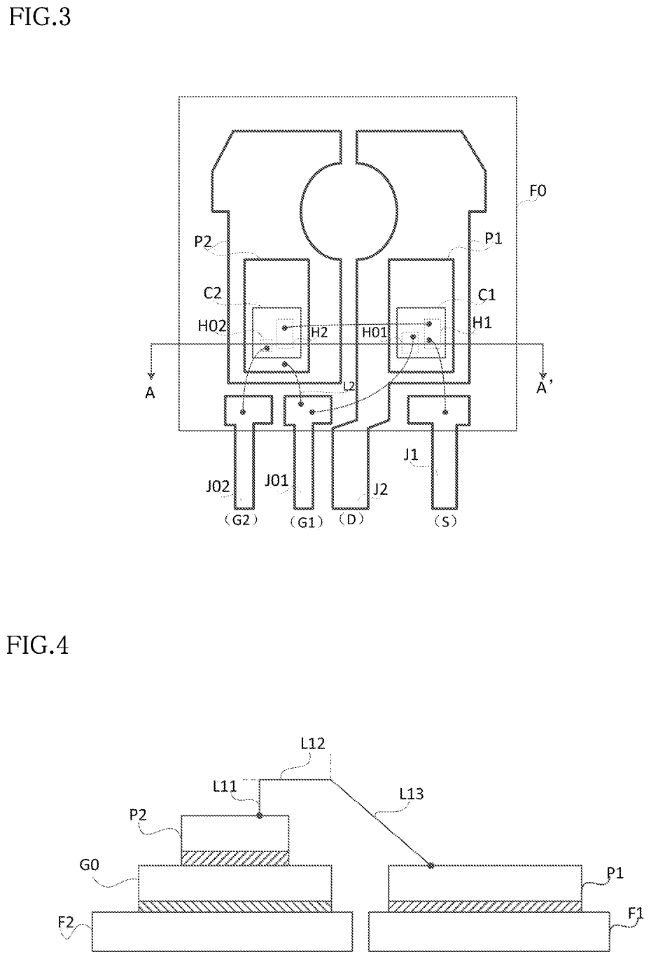

In FIG. 2 and FIG. 3, “(G2)” below J02 indicates that J02 is electrically coupled to the gate electrode G2 of the second transistor, “(G1)” below J01 indicates that J01 is electrically coupled to the gate electrode G1 of the first transistor, “(D)” below J2 indicates that J2 is electrically coupled to the drain electrode D of the first transistor, and “(S)” below J1 indicates that J1 is electrically coupled to the source electrode S of the first transistor.

In at least one embodiment of the present disclosure, the first chip support member is arranged at a first side of the second chip support member, an on-state current of the first transistor is greater than an on-state current of the second transistor, and a turn-on speed of the first transistor is greater than a turn-on speed of the second transistor.

During the implementation, the first side is a right side or a left side, the on-state current of the MOSFET made of SiC is greater than the on-state current of the MOSFET made of Si, and the turn-on speed of the MOSFET made of SiC is greater than the turn-on speed of the MOSFET made of Si.

The semiconductor device in FIG. 3 differs from that in FIG. 2 in that, the second chip support member P2 is electrically coupled to the first control electrode pin J01 through a second lead L2 so as to enable the first electrode of the second transistor to be electrically coupled to the control electrode of the first transistor, and the first control electrode pin J01 is arranged closer to the second chip support member P2 so as to shorten the second lead L2, thereby to ensure an optimum clamping effect and simplify the wiring. In addition, in a connection method for the semiconductor device in FIG. 3, a composition position for a connection member desired for a wire and a pin is located on the pin rather than on the chip, so it is able to provide the connection member with a larger connection area, thereby to facilitate the manufacture.

FIG. 4 is a sectional view of the semiconductor device along line A-A′ in FIG. 3.

As shown in FIG. 4, the first chip support member P1 is arranged on a first substrate F1, and the second chip support member P2 is arranged on a second substrate F2. The first semiconductor chip is arranged on the first chip support member P1, and the second semiconductor chip is arranged on the second chip support member P2. A second distance between the second chip support member P2 and the first substrate F1 is greater than a first distance L between the first chip support member P1 and the first substrate F1. An isolation layer G0 is arranged between the second chip support member P2 and the substrate so as to raise the second chip support member P2 to a level higher than the first chip support member P1. The isolation layer G0 is adhered to the substrate F1 and the second chip support member P2 through an insulating adhesive material.

In some possible embodiments of the present disclosure, the isolation layer G0 is made of Al₂O₃, and the first chip support member P1 is arranged on the first substrate F1 through a tin solder paste. However, the present disclosure is not limited thereto.

As shown in FIG. 4, the second chip support member P2 is located at a level higher than the first chip support member P1. In this way, during the formation of the lead between the second electrode of the second transistor and the second terminal of the first transistor, it is able to increase a stress applied to the second transistor and reduce a stress applied to the first transistor, thereby to protect the first transistor from damage.

As shown in FIG. 4, the second electrode of the second transistor (not shown in FIG. 4, and the second transistor is formed on the second semiconductor chip) is electrically coupled to the second terminal of the first transistor (not shown in FIG. 4, and the first transistor is formed on the first semiconductor chip) through a lead. The lead includes a first lead portion L11, a second lead portion L12 and a third lead portion L13. A first end of the first lead portion L11 is electrically coupled to the second electrode of the second transistor, a second end of the first lead portion L11 is electrically coupled to a first end of the second lead portion L12, a second end of the second lead portion L12 is electrically coupled to a first end of the third lead portion L13, and a second end of the third lead portion L13 is electrically coupled to the second terminal of the first transistor.

A wire for connecting the two semiconductor chips is electrically coupled to each semiconductor chip at a corresponding end. In at least one embodiment of the present disclosure, the semiconductor chip at a high level is coupled to the wire, and then the semiconductor chip at a low level is coupled to the wire. In this way, the second upper surface of the second chip support member P2 is perpendicular to the first lead portion L11, and the first upper surface of the first chip support member P1 is not perpendicular to the third lead portion L13, so as to increase a stress applied to the second transistor and reduce a stress applied to the first transistor, thereby to protect the first transistor from damage. In another possible embodiment of the present disclosure, the semiconductor device further includes a first chip support member, a second chip support member, a first semiconductor chip, a second semiconductor chip, a first control electrode pin and a second control electrode pin. At least a part of the first chip support member, at least a part of the second chip support member, the first semiconductor chip and the second semiconductor chip are encapsulated by the same encapsulation body. The first transistor is formed on the first semiconductor chip, and the second transistor is formed on the second semiconductor chip. The first semiconductor chip is provided with a first surface and a first back surface opposite to the first surface, and the second semiconductor chip is provided with a second surface and a second back surface opposite to the second surface. A first control electrode pad and a first pad are formed on the first surface of the first semiconductor chip, the first back surface is electrically coupled to the first terminal of the first transistor, the first control electrode pad is electrically coupled to the control electrode of the first transistor and the first control electrode pin respectively, and the first pad is electrically coupled to the second terminal of the first transistor. A second control electrode pad and a second pad are formed on the first surface of the second semiconductor chip, the second back surface is electrically coupled to the first electrode of the second transistor, the second control electrode pad is electrically coupled to the control electrode of the second transistor and the second control electrode pin respectively, and the second electrode of the second transistor is electrically coupled to the second pad. The first chip support member is provided with a first upper surface, the first semiconductor chip is supported on the first upper surface of the first chip support member, and the first back surface of the first semiconductor chip faces the first upper surface and is electrically coupled to the first chip support member. The second chip support member is provided with a second upper surface and a second lower surface opposite to the second upper surface, the second chip support member is supported on the first upper surface of the first chip support member, the second chip support member is insulated from the first chip support member, and the second lower surface of the second chip support member faces the first upper surface. The second semiconductor chip is supported on the second upper surface of the second chip support member, and the second back surface of the second semiconductor chip faces the second upper surface and is electrically coupled to the second chip support member.

During the implementation, the semiconductor device further includes a first chip support member, a second chip support member, a first semiconductor chip, a second semiconductor chip, a first control electrode pin and a second control electrode pin. The first transistor is formed on the first semiconductor chip, and the second transistor is formed on the second semiconductor chip. At least a part of the first chip support member, at least a part of the second chip support member, the first semiconductor chip and the second semiconductor chip are encapsulated by the same encapsulation body. The first semiconductor chip and the second chip support member are supported on the first chip support member, the first chip support member is insulated from the second chip support member, and the second semiconductor chip is supported on the second chip support member.

In some possible embodiments of the present disclosure, the second chip support member is electrically coupled to the first control electrode pad through a lead, so that the first electrode of the second transistor is electrically coupled to the control electrode of the first transistor. The second pad is electrically coupled to the first pad, so that the second electrode of the second transistor is electrically coupled to the second terminal of the first transistor. The lead between the second chip support member and the first control electrode pad is short.

In some possible embodiments of the present disclosure, the second chip support member is electrically coupled to the first control electrode pin through a lead, so that the first electrode of the second transistor is electrically coupled to the control electrode of the first transistor. The second pad is electrically coupled to the first pad, so that the second electrode of the second transistor is electrically coupled to the second terminal of the first transistor. The lead between the second chip support member and the first control electrode pin is short.

In at least one embodiment of the present disclosure, the semiconductor device further includes a first electrode pin and a second electrode pin. The first electrode pin is electrically coupled to the first pad, so that the first electrode pin is electrically coupled to the second terminal of the first transistor. The second electrode pin is electrically coupled to the first chip support member, so that the second electrode pin is electrically coupled to the first terminal of the first transistor.

In actual use, at least a part of each of the first electrode pin and the second electrode pin is arranged outside the encapsulation body, but the present disclosure is not limited thereto.

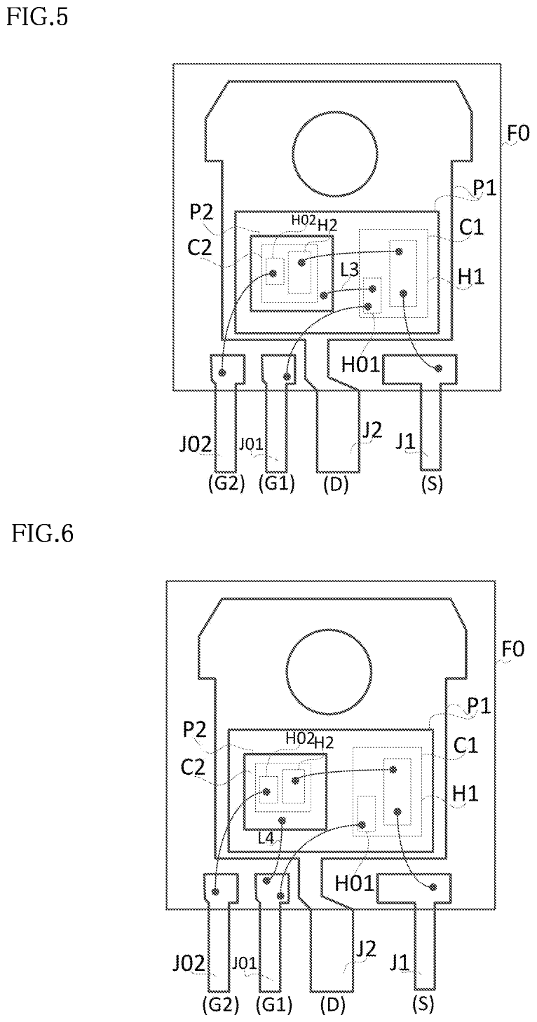

As shown in FIG. 5, the semiconductor device in at least one embodiment of the present disclosure includes a first transistor, a second transistor, an encapsulation body F0, a first chip support member P1, a second chip support member P2, a first semiconductor chip C1, a second semiconductor chip C2, a first control electrode pin J01, a second control electrode pin J02, a first electrode pin J1 and a second electrode pin J2. The first chip support member P1, the second chip support member P2, the first semiconductor chip C1 and the second semiconductor chip C2 are encapsulated by the same encapsulation body F0. The first transistor is formed on the first semiconductor chip C1, and the second transistor is formed on the second semiconductor chip C2. The first semiconductor chip C1 is provided with a first surface and a first back surface opposite to the first surface, and the second semiconductor chip C2 is provided with a second surface and a second back surface opposite to the second surface. A first control electrode pad H01 and a first pad H1 are formed on the first surface of the first semiconductor chip C1, the first back surface is electrically coupled to the first terminal of the first transistor, the first control electrode pin H01 is electrically coupled to the control electrode of the first transistor and the first control electrode pin J01 respectively, and the first pad H1 is electrically coupled to the second terminal of the first transistor. A second control electrode pad H02 and a second pad H2 are formed on the first surface of the second semiconductor chip C2, the second back surface is electrically coupled to the first electrode of the second transistor, the second control electrode pad H02 is electrically coupled to the control electrode of the second transistor and the second control electrode pin J02 respectively, and the second electrode of the second transistor is electrically coupled to the second pad H2. The first chip support member P1 is provided with a first upper surface, the first semiconductor chip C1 is supported on the first upper surface of the first chip support member P1, and the first back surface of the first semiconductor chip C1 faces the first upper surface and is electrically coupled to the first chip support member P1. The second chip support member P2 is provided with a second upper surface and a second lower surface opposite to the second upper surface, the second chip support member P2 is supported on the first upper surface of the first chip support member P1, the second chip support member P2 is insulated from the first chip support member P1, and the second lower surface of the second chip support member P2 faces the first upper surface. The second semiconductor chip C2 is supported on the second upper surface of the second chip support member P2, and the second back surface of the second semiconductor chip C2 faces the second upper surface and is electrically coupled to the second chip support member P2. The first electrode pin J1 is electrically coupled to the first pad H1, so that the first electrode pin J1 is electrically coupled to the second terminal of the first transistor. The second electrode pin J2 is electrically coupled to the first chip support member P1, so that the second electrode pin J2 is electrically coupled to the first terminal of the first transistor. The second chip support member P2 is electrically coupled to the first control electrode pad H01 through a third lead L3, so that the first electrode of the second transistor is electrically coupled to the control electrode of the first transistor, and the first control electrode pad H01 is arranged closer to the second chip support member P2. In this way, it is able to shorten the third lead L3, thereby to ensure an optimum clamping effect and simplify the wiring. The second pad H2 is electrically coupled to the first pad H1, so that the second electrode of the second transistor is electrically coupled to the second terminal of the first transistor.

In FIG. 5, the control electrode of the first transistor is a gate electrode, the first terminal of the first transistor is a drain electrode, the second terminal of the first transistor is a source electrode, the control electrode of the second transistor is a gate electrode, the first electrode of the second transistor is a drain electrode, and the second electrode of the second transistor is a source electrode. However, the present disclosure is not limited thereto.

In FIG. 5, the first transistor is an MOSFET made of SiC, and the second transistor is an MOSFET made of Si. The first chip support member P1 is, but not limited to, arranged at a right side of the second chip support member P2. In actual use, P1 may also be arranged at a left side of P2.

In FIG. 5, each of the first chip support member P1 and the second chip support member is of a metal plate. The first chip support member P1 is linked to the second electrode pin J2 so as to be formed integrally, and the first chip support member P1 is electrically coupled to the second electrode pin J2. The first control electrode pin J01 and the first electrode pin J1 are arranged in such a manner as to be separated from each other through the second electrode pin J2. To be specific, as shown in FIG. 2, J1 is arranged at a right side of J2, J01 is arranged at a left side of J2, J02 is arranged at a left side of J01, and J02, J01, J2 and J1 are insulated from each other.

In FIG. 5, P1 is arranged at a right side of P2, and J02, J01, J2 and J1 are arranged sequentially from left to right, so as to enable the second control electrode pad H02 on P2 to be arranged closer to J02, enable the first control electrode pad H01 on P1 to be arranged closer to J01, and enable the first pad H1 on P1 to be arranged closer to J1, thereby to facilitate the connection between H02 and J02, the connection between H01 and J01, and the connection between H1 and J1.

In FIG. 5, the first semiconductor chip C1 is supported on the first chip support member P1 through, e.g., a conductive adhesive material made of a silver solder or a tin solder paste, the MOSFET made of SiC is formed on the first semiconductor chip C1, the first back surface of the first semiconductor chip C1 is formed into a drain electrode, and the first control electrode pad H01 and the first pad H1 are formed on the first surface of the first semiconductor chip C1. In other words, the drain electrode of the first transistor is formed on the first back surface of the first semiconductor chip C1, and the first control electrode pad H01 electrically coupled to the gate electrode of the first transistor and the first pad H1 electrically coupled to the source electrode of the first transistor are arranged on the first surface of the first semiconductor chip C1.

In FIG. 5, the second chip support member P2 is arranged on the first upper surface of the first chip support member P1, the second chip support member P2 is insulated from the first chip support member P1, and the second lower surface of the second chip support member P2 faces the first upper surface.

In FIG. 5, the second semiconductor chip C2 is supported on the second chip support member P2 through, e.g., a conductive adhesive material made of a silver solder or a tin solder paste, the MOSFET made of Si is formed on the second semiconductor chip C2, the second back surface of the second semiconductor chip C2 is formed into a drain electrode, and the second control electrode pad H02 and the second pad H2 are formed on the first surface of the second semiconductor chip C2. In other words, the drain electrode of the second transistor is formed on the second back surface of the second semiconductor chip C2, and the second control electrode pad H02 electrically coupled to the gate electrode of the second transistor and the second pad H2 electrically coupled to the source electrode of the second transistor are arranged on the first surface of the second semiconductor chip C2.

In FIG. 5, the first semiconductor chip C1 is supported on the first chip support member P1 through the conductive adhesive material, so that the drain electrode of the first transistor on the back surface of the first semiconductor chip C1 is electrically coupled to the first chip support member P1. The second semiconductor chip C2 is supported on the second chip support member P2 through the conductive adhesive material, so that the drain electrode of the second transistor on the back surface of the second semiconductor chip C2 is electrically coupled to the second chip support member P2.

In FIG. 5, the first chip support member P1, the second chip support member P2, the first semiconductor chip C1, the second semiconductor chip C2, a part of J02, a part of J01, a part of J2 and a part of J1 are encapsulated by the encapsulation body F0.

In at least one embodiment of the present disclosure, the first chip support member is arranged at a first side of the second chip support member, an on-state current of the first transistor is greater than an on-state current of the second transistor, and a turn-on speed of the first transistor is greater than a turn-on speed of the second transistor.

During the implementation, the first side is a right side or a left side, the on-state current of the MOSFET made of SiC is greater than the on-state current of the MOSFET made of Si, and the turn-on speed of the MOSFET made of SiC is greater than the turn-on speed of the MOSFET made of Si.

In FIG. 5 and FIG. 6, “(G2)” below J02 indicates that J02 is electrically coupled to the gate electrode G2 of the second transistor, “(G1)” below J01 indicates that J01 is electrically coupled to the gate electrode G1 of the first transistor, “(D)” below J2 indicates that J2 is electrically coupled to the drain electrode D of the first transistor, and “(S)” below J1 indicates that J1 is electrically coupled to the source electrode S of the first transistor.

The semiconductor device in FIG. 6 differs from that in FIG. 5 in that, the second chip support member P2 is electrically coupled to the first control electrode pin J01 through a fourth lead L4 so as to enable the first electrode of the second transistor to be electrically coupled to the control electrode of the first transistor, and the first control electrode pin J01 is arranged closer to the second chip support member P2 so as to shorten the fourth lead L4, thereby to ensure an optimum clamping effect and simplify the wiring.

In yet another possible embodiment of the present disclosure, the semiconductor device further includes a first chip support member, a second chip support member, a first semiconductor chip, a second semiconductor chip, a first control electrode pin and a second control electrode pin. The first chip support member is insulated from the second chip support member. The first transistor is formed on the first semiconductor chip, and the second transistor is formed on the second semiconductor chip. At least a part of the first chip support member, at least a part of the second chip support member, the first semiconductor chip and the second semiconductor chip are encapsulated by the same encapsulation body. The first semiconductor chip is provided with a first surface and a first back surface opposite to the first surface, and the second semiconductor chip is provided with a second surface and a second back surface opposite to the second surface. A first control electrode pad, at least one first pad and at least one second pad are formed on the first surface of the first semiconductor chip, the first control electrode pad is electrically coupled to the control electrode of the first transistor and the first control electrode pin respectively, the first pad is electrically coupled to the second terminal of the first transistor, and the second pad is electrically coupled to the first terminal of the first transistor. A second control electrode pad and a third pad are formed on the first surface of the second semiconductor chip, the second back surface is electrically coupled to the first electrode of the second transistor, the second control electrode pad is electrically coupled to the control electrode of the second transistor and the second control electrode pin respectively, and the second electrode of the second transistor is electrically coupled to the third pad. The first chip support member is provided with a first upper surface, the first semiconductor chip is supported on the first upper surface of the first chip support member, and the first back surface of the first semiconductor chip faces the first upper surface. The second chip support member is provided with a second upper surface, the second semiconductor chip is supported on the second upper surface of the second chip support member, and the second back surface of the second semiconductor chip faces the second upper surface and is electrically coupled to the second chip support member.

During the implementation, the first pads are electrically coupled to each other and the second pads are electrically coupled to each other, but the present disclosure is not limited thereto.

During the implementation, the first pad is insulated from the second pad and the first control electrode pad, and the second electrode pad is insulated from the first control electrode pad.

In at least one embodiment of the present disclosure, the first transistor is, but not limited to, an FET made of GaN, and the second transistor is, but not limited to, an MOSFET made of Si.

During the implementation, the semiconductor device further includes the first chip support member, the second chip support member, the first semiconductor chip and the second semiconductor chip. The first transistor is formed on the first semiconductor chip, the second transistor is formed on the second semiconductor chip, and the first chip support member is insulated from the second chip support member. At least a part of the first chip support member, at least a part of the second chip support member, the first semiconductor chip and the second semiconductor chip are encapsulated by the same encapsulation body. The first control electrode pad, at least one first pad and at least one second pad are formed on the first surface of the first semiconductor chip, the second control electrode pad and the third pad are formed on the first surface of the second semiconductor chip, the second back surface is electrically coupled to the first electrode of the second transistor and the second chip support member, so that the second chip support member is electrically coupled to the first electrode of the second transistor.

In some possible embodiments of the present disclosure, the second chip support member is electrically coupled to the first control electrode pad through a lead, so that the first electrode of the second transistor is electrically coupled to the control electrode of the first transistor. The third pad is electrically coupled to the first pad, so that the second electrode of the second transistor is electrically coupled to the second terminal of the first transistor. The lead between the second chip support member and the first control electrode pad is short.

In some possible embodiments of the present disclosure, the second chip support member is electrically coupled to the first control electrode pin through a lead, so that the first electrode of the second transistor is electrically coupled to the control electrode of the first transistor. The third pad is electrically coupled to the first pad, so that the second electrode of the second transistor is electrically coupled to the second terminal of the first transistor. The lead between the second chip support member and the first control electrode pin is short.

During the implementation, the semiconductor device further includes a first electrode pin and a second electrode pin. The first electrode pin is electrically coupled to the first pad so that the first electrode pin is electrically coupled to the second terminal of the first transistor, and the second electrode pin is electrically coupled to the second pad so that the second electrode pin is electrically coupled to the first terminal of the first transistor.

In actual use, at least a part of each of the first electrode pin and the second electrode pin is, but not limited to, arranged outside the encapsulation body.

In at least one embodiment of the present disclosure, the first chip support member is arranged at a first side of the second chip support member, an on-state current of the first transistor is greater than an on-state current of the second transistor, and a turn-on speed of the first transistor is greater than a turn-on speed of the second transistor.

In some possible embodiments of the present disclosure, the first side is a left side or a right side. When the first transistor is an FET made of GaN and the second transistor is an MOSFET made of Si, the on-state current of the first transistor is greater than the on-state current of the second transistor, and the turn-on speed of the first transistor is greater than the turn-on speed of the second transistor.

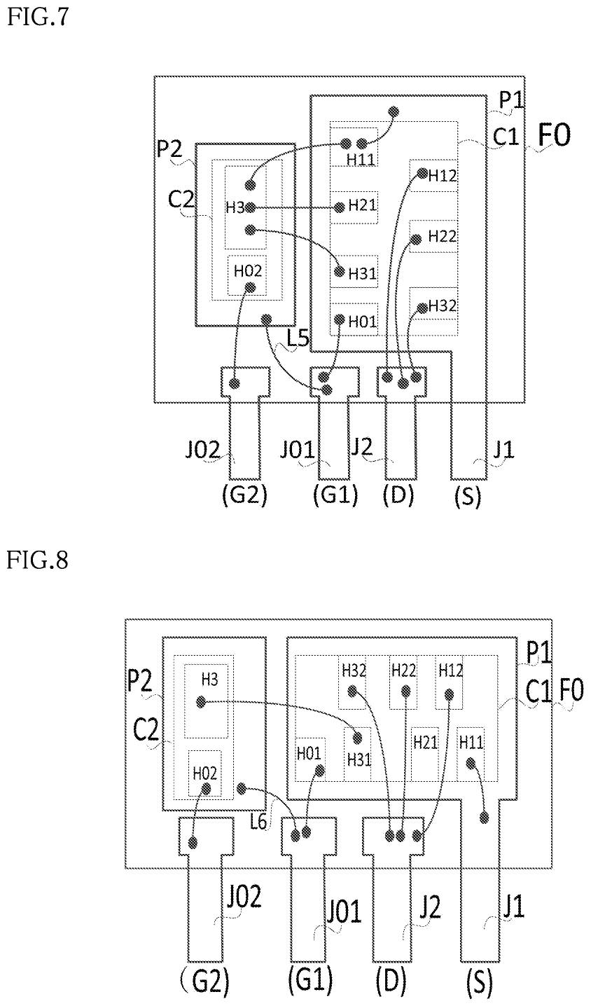

As shown in FIG. 7, the semiconductor device includes a first transistor, a second transistor, an encapsulation body F0, a first chip support member P1, a second chip support member P2, a first semiconductor chip C1, a second semiconductor chip C2, a first control electrode pin J01, a second control electrode pin J02, a first electrode pin J1 and a second electrode pin J2. The first chip support member P1 is insulated from the second chip support member P2. The first transistor is formed on the first semiconductor chip C1, and the second transistor is formed on the second semiconductor chip C2. The first chip support member P1, the second chip support member P2, the first semiconductor chip C1 and the second semiconductor chip C2 are encapsulated by the encapsulation body F0. The first semiconductor chip C1 is provided with a first surface and a first back surface opposite to the first surface, and the second semiconductor chip C2 is provided with a second surface and a second back surface opposite to the second surface. A first control electrode pad H01, a first one of first pads H11, a second one of first pads H21, a third one of first pads H31, a first one of second pads H12, a second one of second pads H22 and a third one of third pads H32 are formed on the first surface of the first semiconductor chip C1, and the first control electrode pad H01 is electrically coupled to the control electrode of the first transistor and the first control electrode pin J01 respectively. H11, H21 and H31 are electrically coupled to each other, and electrically coupled to the second terminal of the first transistor. H12, H22 and H32 are electrically coupled to each other, and electrically coupled to the first terminal of the first transistor. A second control electrode pad H02 and a third pad H3 are formed on the second surface of the semiconductor chip C2, and the second back surface is electrically coupled to a first electrode of the second transistor. The second control electrode pad H02 is electrically coupled to a control electrode of the second transistor and the second control electrode pin J02 respectively, and a second electrode of the second transistor is electrically coupled to the third pad H3. The first chip support member P1 is provided with a first upper surface, the first semiconductor chip C1 is supported on the first upper surface of the first chip support member P1, and the first back surface of the first semiconductor chip C1 faces the first upper surface. The second chip support member P2 is provided with a second upper surface, the second semiconductor chip C2 is supported on the second upper surface of the second chip support member P2, and the second back surface of the second semiconductor chip C2 faces the second upper surface. The second back surface of the second semiconductor chip C2 is electrically coupled to the second chip support member P2, so that the second chip support member P2 is electrically coupled to the first electrode of the second transistor. The first transistor is an FET made of GaN, and the second transistor is an MOSFET made of Si.

In FIG. 7, the second chip support member P2 is electrically coupled to the first control electrode pin J01 through a fifth lead L5, so that the first electrode of the second transistor is electrically coupled to the control electrode of the first transistor. The fifth lead L5 between the second chip support member P2 and the first control electrode pin J01 is short. The third pad H3 is electrically coupled to H11, H21 and H31 respectively, so that the second electrode of the second transistor is electrically coupled to the second terminal of the first transistor.

In FIG. 7, the first chip support member P1 is linked to the first electrode pin J1 so as to be formed integrally, so that the first chip support member P1 is electrically coupled to the first electrode pin J1. H11 is electrically coupled to the first chip support member P1, so that H11 is electrically coupled to J1. In addition, H11, H21 and H31 are electrically coupled to each other, so H21 is electrically coupled to J1 and H31 is electrically coupled to J1. H12, H22 and H32 are electrically coupled to J2 respectively.

In FIG. 7, the control electrode of the first transistor is a gate electrode, the first terminal of the first transistor is a drain electrode, the second terminal of the first transistor is a source electrode, the control electrode of the second transistor is a gate electrode, the first electrode of the second transistor is a drain electrode, and the second electrode of the second transistor is a source electrode. However, the present disclosure is not limited thereto.

In FIG. 7, the first chip support member P1 and the first semiconductor chip C1 are, but not limited to, arranged in a vertical direction.

In FIG. 7, J02, J01, J2 and J1 are arranged sequentially from left to right, and insulated from each other. H11, H21 and H31 are arranged sequentially from top to bottom, H12, H22 and H32 are arranged sequentially from top to bottom, and H11, H21 and H31 are arranged close to the second semiconductor chip C2, so as to enable H11, H21 and H31 to be electrically coupled to H3 conveniently. H01 is arranged at a lower left corner of the first semiconductor chip C1, so as to enable H01 to be electrically coupled to J01 conveniently.

In FIG. 7, the first transistor is an FET made of GaN, and the second transistor is an MOSFET made of Si. The first chip support member P1 is, but not limited to, arranged at a right side of the second chip support member P2. In actual use, P1 may also be arranged at a left side of the second chip support member P2.

In FIG. 7, the first semiconductor chip C1 is supported on the first chip support member P1 through, e.g., a conductive adhesive material made of a silver solder or a tin solder paste, the FET made of GaN is formed on the first semiconductor chip C1, and the first control electrode pad H01, the first one of first pads H11, the second one of first pads H21, the third one of first pads H31, the first one of second pads H12, the second one of second pads H22 and the third one of second pads H32 are formed on the first surface of the first semiconductor chip C1.

In FIG. 7, the second semiconductor chip C2 is supported on the second chip support member P2 through, e.g., a conductive adhesive material made of a silver solder or a tin solder paste, the MOSFET made of Si is formed on the second semiconductor chip C2, the second back surface of the second semiconductor chip C2 is formed into a drain electrode, and the second control electrode pad H02 and the third pad H3 are formed on the first surface of the second semiconductor chip C2. In other words, the drain electrode of the second transistor is formed on the second back surface of the second semiconductor chip C2, and the second control electrode pad H02 electrically coupled to the gate electrode of the second transistor and the third pad H3 electrically coupled to the source electrode of the second transistor are arranged on the first surface of the second semiconductor chip C2.

In FIG. 7, the second semiconductor chip C2 is supported on the second chip support member P2 through the conductive adhesive material, so that the drain electrode of the second transistor on the back surface of the second semiconductor chip C2 is electrically coupled to the second chip support member P2.

In FIG. 7, the first chip support member P1, the second chip support member P2, the first semiconductor chip C1, the second semiconductor chip C2, a part of J02, a part of J01, a part of J2 and a part of J1 are encapsulated by the encapsulation body F0.

In FIG. 7 and FIG. 8, “(G2)” below J02 indicates that J02 is electrically coupled to the gate electrode G2 of the second transistor, “(G1)” below J01 indicates that J01 is electrically coupled to the gate electrode G1 of the first transistor, “(D)” below J2 indicates that J2 is electrically coupled to the drain electrode D of the first transistor, and “(S)” below J1 indicates that J1 is electrically coupled to the source electrode S of the first transistor.

During the implementation, the second chip support member P2 is also electrically coupled to the first control electrode pad H01 through a lead, so that the first electrode of the second transistor is electrically coupled to the control electrode of the first transistor. The lead between the second chip support member P2 and the first control electrode pad H01 is short.

The semiconductor device in FIG. 8 differs from that in FIG. 7 in that, the first chip support member P1 is arranged in a horizontal direction, and the first semiconductor chip C1 is arranged in the horizontal direction, so that H11, H21 and H31 are arranged sequentially from right to left, H12, H22 and H32 are arranged sequentially from right to left, H31 is electrically coupled to H3, and H11 is electrically coupled to J1.

In FIG. 8, the second chip support member P2 is electrically coupled to the first control electrode pin J01 through a sixth lead L6, so that the first electrode of the second transistor is electrically coupled to the control electrode of the first transistor. The sixth lead L6 between the second chip support member P2 and the first control electrode pin J01 is short.

In FIG. 8, the first chip support member P1 is linked to the first electrode pin J1 so as to be formed integrally, so that the first chip support member P1 is electrically coupled to the first electrode pin J1. H11 is electrically coupled to the first chip support member P1, so that H11 is electrically coupled to J1. H11, H21 and H31 are electrically coupled to each other, so that H21 is electrically coupled to J1, and H31 is electrically coupled to J1.

In some possible embodiments of the present disclosure, the first chip support member and the second chip support member are arranged on a same substrate, and a second distance between the second chip support member and the substrate is greater than a first distance between the first chip support member and the substrate.

In actual use, an isolation layer is arranged between the second chip support member and the substrate so as to raise the second chip support member to a level higher than the first chip support member. The isolation layer is adhered to the substrate and the second chip support member through an insulating adhesive material. For example, the isolation layer is made of, but not limited to, Al₂O₃.

During the implementation, the second chip support member is located at a level higher than the first chip support member. In this way, during the formation of the lead between the second electrode of the second transistor and the second terminal of the first transistor, it is able to increase a stress applied to the second transistor and reduce a stress applied to the first transistor, thereby to protect the first transistor from damage.

During the implementation, the second electrode of the second transistor is electrically coupled to the second terminal of the first transistor though a lead. The lead includes a first lead portion, a second lead portion and a third lead portion. A first end of the first lead portion is electrically coupled to the second electrode of the second transistor, a second end of the first lead portion is electrically coupled to a first end of the second lead portion, a second end of the second lead portion is electrically coupled to a first end of the third lead portion, and a second end of the third lead portion is electrically coupled to the second terminal of the first transistor. The second upper surface of the second chip support member is perpendicular to the first lead portion, and the first upper surface of the first chip support member is not perpendicular to the third lead portion, so as to increase a stress applied to the second transistor and reduce a stress applied to the first transistor, thereby to protect the first transistor from damage.

In some possible embodiments of the present disclosure, the semiconductor device further includes a chip support member, a first semiconductor chip and a second semiconductor chip. The first transistor is formed on the first semiconductor chip, and the second transistor is formed on the second semiconductor chip. At least a part of the chip support member, the first semiconductor chip and the second semiconductor chip are encapsulated by the same encapsulation body. The first semiconductor chip is provided with a first surface and a first back surface opposite to the first surface, and the second semiconductor chip is provided with a second surface and a second back surface opposite to the second surface. A first control electrode pad and a first pad are formed on the first surface of the first semiconductor chip, the first back surface is electrically coupled to the first terminal of the first transistor, the first control electrode pad is electrically coupled to the control electrode of the first transistor and the first control electrode pin respectively, and the first pad is electrically coupled to the second terminal of the first transistor. A second control electrode pad, at least one second pad and at least one third pad are formed on the first surface of the second semiconductor chip, the second control electrode pad is electrically coupled to the control electrode of the second transistor and the second control electrode pin respectively, the second electrode of the second transistor is electrically coupled to the second pad, and the first electrode of the second transistor is electrically coupled to the third pad. The chip support member is provided with an upper surface, the first semiconductor chip is supported on the upper surface of the chip support member, and the first back surface of the first semiconductor chip faces the upper surface and is electrically coupled to the chip support member. The second semiconductor chip is supported on the upper surface of the chip support member, and the second back surface of the second semiconductor chip faces the upper surface.

During the implementation, the semiconductor device further includes the chip support member, the first semiconductor chip and the second semiconductor chip. The first transistor is formed on the first semiconductor chip, and the second transistor is formed on the second semiconductor chip. At least a part of the chip support member, the first semiconductor chip and the second semiconductor chip are encapsulated by the same encapsulation body. The first control electrode pad and the first pad are formed on the first surface of the first semiconductor chip, and the first back surface is electrically coupled to the first terminal of the first transistor and the chip support member, so that the first terminal of the first transistor is electrically coupled to the chip support member. The second control pad, at least one second pad and at least one third pad are formed on the first surface of the second semiconductor chip.

In some possible embodiments of the present disclosure, the third pad is electrically coupled to the first control electrode pin through a lead, so that the first electrode of the second transistor is electrically coupled to the control electrode of the first transistor. The second pad is electrically coupled to the first pad, so that the second electrode of the second transistor is electrically coupled to the second terminal of the first transistor. The lead between the third pad and the first control electrode pin is short.

In some possible embodiments of the present disclosure, the third pad is electrically coupled to the first control electrode pad through a lead, so that the first electrode of the second transistor is electrically coupled to the control electrode of the first transistor. The second pad is electrically coupled to the first pad, so that the second electrode of the second transistor is electrically coupled to the second terminal of the first transistor. The lead between the third pad and the first control electrode pad is short.

In at least one embodiment of the present disclosure, the semiconductor device further includes a first electrode pin and a second electrode pin. The first electrode pin is electrically coupled to the first pad, so that the first electrode pin is electrically coupled to the second terminal of the first transistor. The second electrode pin is electrically coupled to the chip support member, so that the second electrode pin is electrically coupled to the first terminal of the first transistor.

During the implementation, the first semiconductor chip is arranged at a first side of the second semiconductor chip, and an on-state current of the first transistor is greater than an on-state current of the second transistor.

In some possible embodiments of the present disclosure, the first transistor is an MOSFET made of SiC, and the second transistor is an FET made of GaN.

In at least one embodiment of the present disclosure, the first side is a left side or a right side. When the first transistor is an MOSFET made of SiC and the second transistor is an FET made of GaN, the on-state current of the first transistor is greater than the on-state current of the second transistor.

In some possible embodiments of the present disclosure, a fourth distance between the first semiconductor chip and the chip support member is greater than a third distance between the first semiconductor chip and the chip support member.

In actual use, an isolation layer is arranged between the second semiconductor chip and the chip support member so as to raise the second semiconductor chip to a level higher than the first semiconductor chip. The isolation layer is adhered to the chip support member and the second semiconductor chip through an insulating adhesive material. For example, the isolation layer is made of, but not limited to, Al₂O₃.

During the implementation, the second semiconductor chip is located at a level higher than the first semiconductor chip. In this way, during the formation of the lead between the second electrode of the second transistor and the second terminal of the first transistor, it is able to increase a stress applied to the second transistor and reduce a stress applied to the first transistor, thereby to protect the first transistor from damage.

During the implementation, the second electrode of the second transistor is electrically coupled to the second terminal of the first transistor though a lead. The lead includes a first lead portion, a second lead portion and a third lead portion. A first end of the first lead portion is electrically coupled to the second electrode of the second transistor, a second end of the first lead portion is electrically coupled to a first end of the second lead portion, a second end of the second lead portion is electrically coupled to a first end of the third lead portion, and a second end of the third lead portion is electrically coupled to the second terminal of the first transistor. The second surface of the second semiconductor chip is perpendicular to the first lead portion, and the first surface of the first semiconductor chip is not perpendicular to the third lead portion, so as to increase a stress applied to the second transistor and reduce a stress applied to the first transistor, thereby to protect the first transistor from damage.

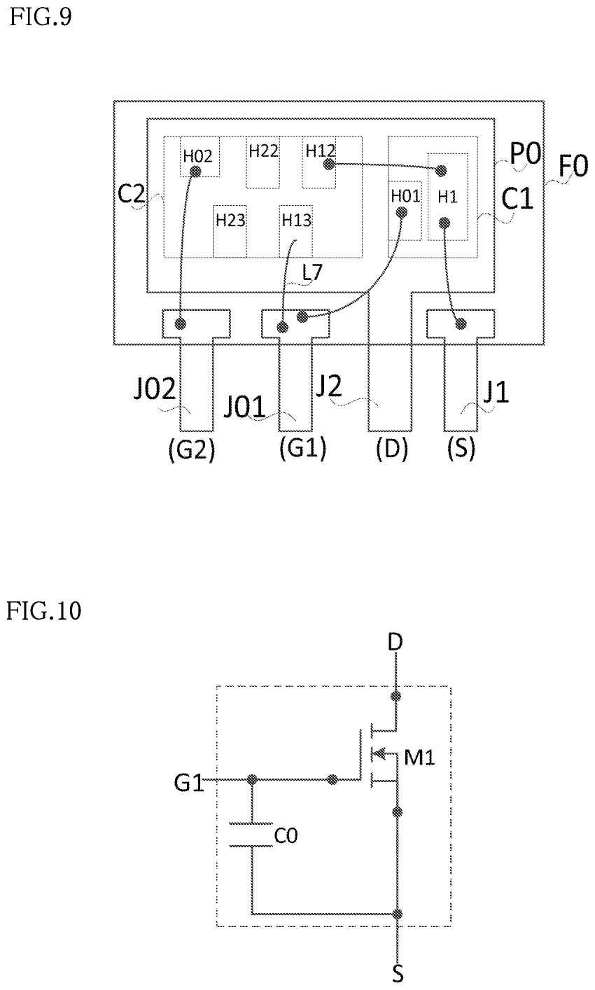

As shown in FIG. 9, the semiconductor device includes a first transistor, a second transistor, an encapsulation body F0, a chip support member P0, a first semiconductor chip C1, a second semiconductor chip C2, a first control electrode pin J01, a second control electrode pin J02, a first electrode pin J1 and a second electrode pin J2. The first transistor is formed on the first semiconductor chip C1, and the second transistor is formed on the second semiconductor chip C2. The chip support member P0, the first semiconductor chip C1 and the second semiconductor chip C2 are encapsulated by a same encapsulation body. The first semiconductor chip C1 is provided with a first surface and a first back surface opposite to the first surface, and the second semiconductor chip C2 is provided with a second surface and a second back surface opposite to the second surface. A first control electrode pad H01 and a first pad H1 are formed on the first surface of the first semiconductor chip C1, the first back surface is electrically coupled to the first terminal of the first transistor, the first control electrode pad H01 is electrically coupled to the control electrode of the first transistor and the first control electrode pin J01 respectively, and the first had H1 is electrically coupled to the second terminal of the first transistor. A second control electrode pad H02, a first one of second pads H12, a second one of second pads H22, a first one of third pads H13 and a second one of third pads H23 are formed on the first surface of the second semiconductor chip, the second control electrode pad H02 is electrically coupled to the control electrode of the second transistor and the second control electrode pin J02 respectively, the second electrode of the second transistor is electrically coupled to H12 and H22, and the first electrode of the second transistor is electrically coupled to H13 and H23. H12 is electrically coupled to H22, and H13 is electrically coupled to H23. The chip support member P0 is provided with an upper surface, the first semiconductor chip C1 is supported on the upper surface of the chip support member P0, and the first back surface of the first semiconductor chip C1 faces the upper surface. The first back surface of the first semiconductor chip C1 is electrically coupled to the chip support member P0, so that the first terminal of the first transistor is electrically coupled to the chip support member P0. The second semiconductor chip C2 is supported on the upper surface of the chip support member P0, and the second back surface of the second semiconductor chip C2 faces the upper surface. The first electrode pin J1 is electrically coupled to the first pad H1, so that the first electrode pin J1 is electrically coupled to the second terminal of the first transistor. The second electrode pin J2 is electrically coupled to the chip support member P0, so that the second electrode pin J2 is electrically coupled to the first terminal of the first transistor. H13 is electrically coupled to the first control electrode pin J01 through a seventh lead L7, so that the first electrode of the second transistor is electrically coupled to the control electrode of the first transistor. H12 is electrically coupled to the first pad H1, so that the second electrode of the second transistor is electrically coupled to the second terminal of the first transistor. The seventh lead L7 between H13 and the first control electrode pin J01 is short.

In FIG. 9, the control electrode of the first transistor is a gate electrode, the first terminal of the first transistor is a drain electrode, the second terminal of the first transistor is a source electrode, the control electrode of the second transistor is a gate electrode, the first electrode of the second transistor is a drain electrode, and the second electrode of the second transistor is a source electrode. However, the present disclosure is not limited thereto.

In FIG. 9, the chip support member P0 is linked to the second electrode pin J2 so as to be formed integrally, so that the second chip support member P0 is electrically coupled to the second electrode pin J2.

In FIG. 9, J02, J01, J2 and J1 are arranged sequentially from left to right, and insulated from each other. H12 and H22 are arranged sequentially from right to left, H13 and H23 are arranged sequentially from right to left, and H13 is arranged close to J01, so as to enable H13 to be electrically coupled to J01 conveniently.

In FIG. 9, the first transistor is an MOSFET made of SiC, and the second transistor is an FET made of GaN. The first semiconductor chip C1 is, but not limited to, arranged at a right side of the second semiconductor chip C2. In actual use, C1 may also be arranged at a left side of C2.

In FIG. 9, the first semiconductor chip C1 is supported on the chip support member P0 through, e.g., a conductive adhesive material made of a silver solder or a tin solder paste, the MOSFET made of SiC is formed on the first semiconductor chip C1, the first back surface of the first semiconductor chip C1 is formed into the drain electrode, and the first control electrode pad H01 and the first pad H1 are formed on the first surface of the first semiconductor chip C1. In other words, the drain electrode of the first transistor is formed on the first back surface of the first semiconductor chip C1, and the first control electrode pad H01 electrically coupled to the gate electrode of the first transistor and the first pad H1 electrically coupled to the source electrode of the first transistor are arranged on the first surface of the first semiconductor chip C1.

In FIG. 9, the second semiconductor chip C2 is supported on the upper surface of the chip support member P0, and the second back surface of the second semiconductor chip C2 faces the upper surface and is insulated from the chip support member P0.

In FIG. 9, the chip support member P0, the first semiconductor chip C1, the second semiconductor chip C2, a part of J02, a part of J01, a part of J2 and a part of J1 are encapsulated by the encapsulation body F0.

In FIG. 9, “(G2)” below J02 indicates that J02 is electrically coupled to the gate electrode G2 of the second transistor, “(G1)” below J01 indicates that J01 is electrically coupled to the gate electrode G1 of the first transistor, “(D)” below J2 indicates that J2 is electrically coupled to the drain electrode D of the first transistor, and “(S)” below J1 indicates that J1 is electrically coupled to the source electrode S of the first transistor.

During the implementation, the first one of third pads H13 is electrically coupled to the first control electrode pad H01 through a lead, so that the first electrode of the second transistor is electrically coupled to the control electrode of the first transistor. The lead between the first one of third pads H13 and the first control electrode pad H01 is short.

The present disclosure further provides in some embodiments a semiconductor device, which includes an encapsulation body, a first transistor and a capacitor. The first transistor includes a control electrode, a first terminal and a second terminal, and the capacitor includes a first capacitor electrode and a second capacitor electrode. The first transistor is configured to allow a current to flow from the first terminal to the second terminal under the control of a potential at the control electrode of the first transistor. The first capacitor electrode is electrically coupled to the control electrode of the first transistor, and the second capacitor electrode is electrically coupled to the second terminal of the first transistor. The first transistor and the capacitor are encapsulated by the same encapsulation body, and the control electrode of the first transistor is electrically coupled to a first control electrode pin.

In at least one embodiment of the present disclosure, the control electrode of the first transistor is electrically coupled to the first control electrode pin through a binding wire, and the binding wire is a lead.

According to the semiconductor device in the embodiments of the present disclosure, the first transistor and the capacitor (the capacitor is used to control the potential at the control electrode of the first transistor) are encapsulated by the same encapsulation body, so as to shorten a distance between the capacitor and the control electrode of the first transistor, thereby to ensure a better clamping effect and simplify the wiring.

During the implementation, at least a part of the first control electrode pin is, but not limited to, arranged outside the encapsulation body.

During the implementation, the encapsulation body is made of, but not limited to, resin.

In some possible embodiments of the present disclosure, the first transistor is an N-type transistor, the first terminal is a first electrode, the first electrode is a drain electrode, the second terminal is a second electrode, and the second electrode is a source electrode; or the first transistor is a P-type transistor, the first terminal is a first electrode, the first electrode is a source electrode, the second terminal is a second electrode, and the second electrode is a drain electrode.

During the implementation, the semiconductor device further includes a chip support member, a first semiconductor chip, a second semiconductor chip and a first control electrode pin. The first transistor is formed on the first semiconductor chip and the capacitor is formed on the second semiconductor chip. At least a part of the chip support member, the first semiconductor chip and the second semiconductor chip are encapsulated by the same encapsulation body. The first semiconductor chip is provided with a first surface and a first back surface opposite to the first surface, and the second semiconductor chip is provided with a second surface and a second back surface opposite to the second surface. A first control electrode pad and a first pad are formed on the first surface of the first semiconductor chip, the first back surface is electrically coupled to the first terminal of the first transistor, the first control electrode pad is electrically coupled to the control electrode of the first transistor and the first control electrode pin respectively, and the first pad is electrically coupled to the second terminal of the first transistor. A first electrode pad and a second electrode pad are formed on the first surface of the second semiconductor chip, the first electrode pad is electrically coupled to the first capacitor electrode, and the second electrode pad is electrically coupled to the second capacitor electrode. The chip support member is provided with an upper surface, the first semiconductor chip is supported on the upper surface of the chip support member, and the first back surface of the first semiconductor chip faces the upper surface and is electrically coupled to the chip support member. The second semiconductor chip is supported on the upper surface of the chip support member, and the second back surface of the second semiconductor chip faces the upper surface. The first electrode pad is electrically coupled to the first control electrode pin or the first control electrode pad, and the second electrode pad is electrically coupled to the first pad, so that the second capacitor electrode is electrically coupled to the second terminal of the first transistor.

In at least one embodiment of the present disclosure, the semiconductor device further includes a chip support member, a first semiconductor chip, a second semiconductor chip and a first control electrode pin. The first transistor is formed on the first semiconductor chip, and the capacitor is formed on the second semiconductor chip. At least a part of the chip support member, the first semiconductor chip and the second semiconductor chip are encapsulated by the same encapsulation body. The first transistor is an MOSFET made of SiC, the first electrode pad is electrically coupled to the first control electrode pin or the first control electrode pad, and a lead between the first electrode pad and the first control electrode pin or the first control electrode pad is short.

In some possible embodiments of the present disclosure, the semiconductor device further includes a first electrode pin and a second electrode pin, the first electrode pin is electrically coupled to the first pad, and the second electrode pin is electrically coupled to the chip support member.

During the implementation, at least a part of the first control electrode pin is arranged outside the encapsulation body, at least a part of the first electrode pin is arranged outside the encapsulation body, and at least a part of the second electrode pin is arranged outside the encapsulation body.

As shown in FIG. 10, the semiconductor device includes a first transistor M1 and a capacitor C0, and the capacitor C0 includes a first capacitor electrode and a second capacitor electrode. The first transistor M1 is configured to allow a current to flow from a drain electrode D of the first transistor M1 to a source electrode S of the first transistor M1 under the control of a potential at a gate electrode G1 of the first transistor M1. The first capacitor electrode is electrically coupled to the gate electrode G1 of the first transistor M1, and the second capacitor electrode is electrically coupled to the source electrode S of the first transistor M1.

In FIG. 10, M1 is, but not limited to, an N-type MOSFET.

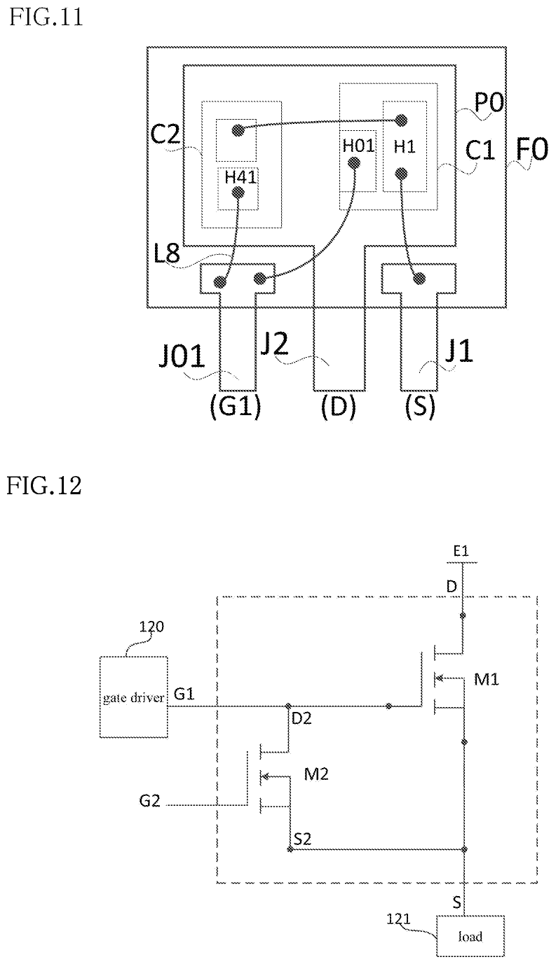

As shown in FIG. 11, the semiconductor device includes a first transistor, a capacitor, an encapsulation body F0, a chip support member P0, a first semiconductor chip C1, a second semiconductor chip C2, a first control electrode pin J01, a first electrode pin J1 and a second electrode pin J2. The first transistor is formed on the first semiconductor chip C1, and the capacitor is formed on the second semiconductor chip C2. The chip support member P0, the first semiconductor chip C1 and the second semiconductor chip C2 are encapsulated by the same encapsulation body F0. The first semiconductor chip C1 is provided with a first surface and a first back surface opposite to the first surface, and the second semiconductor chip C2 is provided with a second surface and a second back surface opposite to the second surface. A first control electrode pad H01 and a first pad H1 are formed on the first surface of the first semiconductor chip C1, the first back surface is electrically coupled to the first terminal of the first transistor, the first control electrode pad H01 is electrically coupled to a control electrode of the first transistor and the first control electrode pin J01, and the first pad H1 is electrically coupled to a second terminal of the first transistor. A first electrode pad H41 and a second electrode pad H42 are formed on the first surface of the second semiconductor chip C2, the first electrode pad H41 is electrically coupled to a first capacitor electrode, and the second electrode pad H42 is electrically coupled to a second capacitor electrode. The chip support member P0 is provided with an upper surface, the first semiconductor chip C1 is supported on the upper surface of the chip support member P0, and the first back surface of the first semiconductor chip C1 faces the upper surface and is electrically coupled to the chip support member P0. The second semiconductor chip C2 is supported on the upper surface of the chip support member, and the second back surface of the second semiconductor chip C2 faces the upper surface. The second electrode pad H41 is electrically coupled to the first pad H1. The first electrode pad H41 is electrically coupled to the first control electrode pin J01 through an eighth lead L8, so that the first capacitor electrode is electrically coupled to the control electrode of the first transistor. The second electrode pad 42 is electrically coupled to the first pad H1, so that the second capacitor electrode is electrically coupled to the second terminal of the first transistor. The eighth lead L8 between the first electrode pad H41 and the first control electrode pin J01 is short. The first electrode pin J1 is electrically coupled to the first pad H1, so that the first electrode pin J1 is electrically coupled to the second terminal of the first transistor. The second electrode pin J2 is electrically coupled to the chip support member P0, so that the second electrode pin J2 is electrically coupled to the first terminal of the first transistor.

In FIG. 11, the first transistor is an N-type transistor, the first terminal is a first electrode, the first electrode is a drain electrode, the second terminal is a second electrode, and the second electrode is a source electrode.

In FIG. 11, “(G1)” below J01 indicates that J01 is electrically coupled to the gate electrode G1 of the first transistor, “(D)” below J2 indicates that J2 is electrically coupled to the drain electrode D of the first transistor, and “(S)” below J1 indicates that J1 is electrically coupled to the source electrode S of the first transistor.

In FIG. 11, the first transistor is an MOSFET made of SiC. The first semiconductor chip C1 is, but not limited to, arranged at a right side of the second semiconductor chip C2. In actual use, Cl may also be arranged at a left side of C2.

In FIG. 11, during the manufacture of a SiC MOSFET wafer, the capacitor may be arranged in a very small area, so as to integrate the capacitor into the SiC MOSFET inside.

In FIG. 11, the chip support member P0 is linked to the second electrode pin J2 so as to be formed integrally, and the chip support member P0 is electrically coupled to the second electrode pin J2. The first control electrode pin J01 and the first electrode pin J1 are arranged in such a manner as to be separated from each other through the second electrode pin J2. To be specific, as shown in FIG. 10, J1 is arranged at a right side of J2, J01 is arranged at a left side of J2, and J01, J2 and J1 are insulated from each other.

In FIG. 11, the first semiconductor chip C1 is supported on the chip support member P0 through, e.g., a conductive adhesive material made of a silver solder or a tin solder paste, the MOSFET made of SiC is formed on the first semiconductor chip C1, the first back surface of the first semiconductor chip C1 is formed into a drain electrode, and the first control electrode pad H01 and the first pad H1 are formed on the first surface of the first semiconductor chip C1. In other words, the drain electrode of the first transistor is formed on the first back surface of the first semiconductor chip C1, and the first control electrode pad H01 electrically coupled to the gate electrode of the first transistor and the first pad H1 electrically coupled to the source electrode of the first transistor are arranged on the first surface of the first semiconductor chip C1.

During the implementation, the second back surface of the second semiconductor chip C2 faces the upper surface of the chip support member P0 and is insulated from the chip support member P0, but the present disclosure is not limited thereto.

In FIG. 11, the second semiconductor chip C2 is arranged on the chip support member P0, the capacitor is formed on the second semiconductor chip C2, and a first electrode pad H41 and a second electrode pad H42 are formed on the first surface of the second semiconductor chip C2.

In FIG. 11, the chip support member P0, the first semiconductor chip C1, the second semiconductor chip C2, a part of J01, a part of J2 and a part of J1 are encapsulated by the encapsulation body F0.

In at least one embodiment of the present disclosure, a switching system includes a gate driver and the above-mentioned semiconductor device. The gate driver is configured to apply a gate driving signal to the control electrode of the first transistor in the semiconductor device, so as to turn on or off the first transistor. The first electrode of the first transistor is electrically coupled to a power source end, and the second electrode of the first transistor is electrically coupled to a load. When the first transistor is turned on, the power source end is configured to apply a power source voltage to the load.

As shown in FIG. 12, the switching system includes a gate driver 120 and the semiconductor device in FIG. 1. The gate driver 120 is electrically coupled to the gate electrode G1 of M1 through a resistor R, the drain electrode D of M1 is electrically coupled to a power source end E1, and the source electrode S of M1 is electrically coupled to a load 121.

During the operation of the switching system in FIG. 12, when it is necessary to enable E1 to be electrically coupled to the load 121, the gate driver 120 applies a gate driving signal to the gate electrode G1 of M1, so as to turn on M1, thereby to control the power source end E1 to be electrically coupled to the load 121.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

The present disclosure includes the embodiments described in the following clauses.
Clause 1. A semiconductor device, comprising an encapsulation body, a first transistor and a second transistor,
wherein the first transistor comprises a control electrode, a first terminal and a second terminal;
the first transistor is configured to allow a current to flow from the first terminal to the second terminal under the control of a potential at the control electrode of the first transistor;
a first electrode of the second transistor is electrically coupled to the control electrode of the first transistor, and a second electrode of the second transistor is electrically coupled to the second terminal of the first transistor; and
the first transistor and the second transistor are encapsulated by the same encapsulation body, the control electrode of the first transistor is electrically coupled to a first control electrode pin, and a control electrode of the second transistor is electrically coupled to a second control electrode pin.
Clause 2. The semiconductor device according to clause 1, wherein the first transistor is an N-type transistor, the first terminal is a first electrode, the first electrode is a drain electrode, the second terminal is a second electrode, and the second electrode is a source electrode; or
the first transistor is a P-type transistor, the first terminal is a first electrode, the first electrode is a source electrode, the second terminal is a second electrode, and the second electrode is a drain electrode.
Clause 3. The semiconductor device according to clause 2, further comprising a first chip support member, a second chip support member, a first semiconductor chip, a second semiconductor chip, a first control electrode pin and a second control electrode pin,
wherein the first chip support member is insulated from the second chip support member;
the first transistor is formed on the first semiconductor chip, and the second transistor is formed on the second semiconductor chip;
at least a part of the first chip support member, at least a part of the second chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad and a first pad are formed on the first surface of the first semiconductor chip, and the first back surface is electrically coupled to the first terminal of the first transistor;
the first control electrode pad is electrically coupled to the control electrode of the first transistor and the first control electrode pad respectively, and the first pad is electrically coupled to the second terminal of the first transistor;
a second control electrode pad and a second pad are formed on the first surface of the second semiconductor chip, and the second back surface is electrically coupled to the first electrode of the second transistor;
the second control electrode pad is electrically coupled to the control electrode of the second transistor and the second control electrode pin respectively, and the second electrode of the second transistor is electrically coupled to the second pad;
the first chip support member is provided with a first upper surface, the first semiconductor chip is supported on the first upper surface of the first chip support member, and the first back surface of the first semiconductor chip faces the first upper surface and is electrically coupled to the first chip support member; and
the second chip support member is provided with a second upper surface, the second semiconductor chip is supported on the second upper surface of the second chip support member, and the second back surface of the second semiconductor chip faces the second upper surface and is electrically coupled to the second chip support member.
Clause 4. The semiconductor device according to clause 3, wherein the second chip support member is electrically coupled to the first control electrode pad through a lead, and the second pad is electrically coupled to the first pad.
Clause 5. The semiconductor device according to clause 3, wherein the second chip support member is electrically coupled to the first control electrode pin through a lead, and the second pad is electrically coupled to the first pad.
Clause 6. The semiconductor device according to any of clauses 3 to 5, further comprising a first electrode pin and a second electrode pin, wherein the first electrode pin is electrically coupled to the first pad, and the second electrode pin is electrically coupled to the first chip support member.
Clause 7. The semiconductor device according to any of clauses 3 to 5, wherein the first chip support member is arranged at a first side of the second chip support member, an on-state current of the first transistor is greater than an on-state current of the second transistor, and a turn-on speed of the first transistor is greater than a turn-on speed of the second transistor.
Clause 8. The semiconductor device according to clause 2, further comprising a first chip support member, a second chip support member, a first semiconductor chip, a second semiconductor chip, a first control electrode pin and a second control electrode pin,
wherein at least a part of the first chip support member, at least a part of the second chip support member, the first semiconductor chip and the second semiconductor chip are encapsulated by the same encapsulation body;
the first transistor is formed on the first semiconductor chip, and the second transistor is formed on the second semiconductor chip;
the first semiconductor chip is provided with a first surface and a first back surface opposite to the first surface, and the second semiconductor chip is provide with a second surface and a second back surface opposite to the second surface;
a first control electrode pad and a first pad are formed on the first surface of the first semiconductor chip, and the first back surface is electrically coupled to the first terminal of the first transistor;
the first control electrode pad is electrically coupled to the control electrode of the first transistor and the first control electrode pin respectively, and the first pad is electrically coupled to the second terminal of the first transistor;
a second control electrode pad and a second pad are formed on the first surface of the second semiconductor chip, and the second back surface is electrically coupled to the first electrode of the second transistor;
the second control electrode pad is electrically coupled to the control electrode of the second transistor and a second control electrode pin respectively, and the second electrode of the second transistor is electrically coupled to the second pad;
the first chip support member is provided with a first upper surface, the first semiconductor chip is supported on the first upper surface of the first chip support member, and the first back surface of the first semiconductor chip faces the first upper surface and is electrically coupled to the first chip support member;
the second chip support member is provided with a second upper surface and a second lower surface opposite to the second upper surface, the second chip support member is supported on the first upper surface of the first chip support member, the second chip support member is insulated from the first chip support member, and the second lower surface of the second chip support member faces the first upper surface; and
the second semiconductor chip is supported on the second upper surface of the second chip support member, and the second back surface of the second semiconductor chip faces the second upper surface and is electrically coupled to the second chip support member.
Clause 9. The semiconductor device according to clause 8, wherein the second chip support member is electrically coupled to the first control electrode pad through a lead, and the second pad is electrically coupled to the first pad.
Clause 10. The semiconductor device according to any of clauses 8 to 10, wherein the second chip support member is electrically coupled to the first control electrode pin through a lead, and the second pad is electrically coupled to the first pad.
Clause 11. The semiconductor device according to any of clauses 8 to 10, further comprising a first electrode pin and a second electrode pin, wherein the first electrode pin is electrically coupled to the first pad, and the second electrode pin is electrically coupled to the first chip support member.
Clause 12. The semiconductor device according to any of clauses 8 to 10, wherein the first semiconductor chip is arranged at a first side of the second semiconductor chip, an on-state current of the first transistor is greater than an on-state current of the second transistor, and a turn-on speed of the first transistor is greater than a turn-on speed of the second transistor.
Clause 13. The semiconductor device according to any of clauses 3 to 5 and 8 to 10, wherein the first transistor is a Metal-Oxide-Semiconductor Field Effect Transistor (MOSFET) made of SiC, and the second transistor is an MOSFET made of Si.
Clause 14. The semiconductor device according to clause 2, further comprising a first chip support member, a second chip support member, a first semiconductor chip, a second semiconductor chip, a first control electrode pin and a second control electrode pin,
wherein the first chip support member is insulated from the second chip support member; the first transistor is formed on the first semiconductor chip, and the second transistor is formed on the second semiconductor chip;
at least a part of the first chip support member, at least a part of the second chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad, at least one first pad and at least one second pad are formed on the first surface of the first semiconductor chip, the first control electrode pad is electrically coupled to the control electrode of the first transistor and the first control electrode pin respectively, the first pad is electrically coupled to the second terminal of the first transistor, and the second pad is electrically coupled to the first terminal of the first transistor;
a second control electrode pad and a third pad are formed on the first surface of the second semiconductor chip, the second back surface is electrically coupled to the first electrode of the second transistor, the second control electrode pad is electrically coupled to the control electrode of the second transistor and the second control electrode pin respectively, and the second electrode of the second transistor is electrically coupled to the third pad;
the first chip support member is provided with a first upper surface, the first semiconductor chip is supported on the first upper surface of the first chip support member, and the first back surface of the first semiconductor chip faces the first upper surface; and
the second chip support member is provided with a second upper surface, the second semiconductor chip is supported on the second upper surface of the second chip support member, and the second back surface of the second semiconductor chip faces the second upper surface and is electrically coupled to the second chip support member.
Clause 15. The semiconductor device according to clause 14, wherein the second chip support member is electrically coupled to the first control electrode pad through a lead, and the third pad is electrically coupled to the first pad.
Clause 16. The semiconductor device according to clause 14, wherein the second chip support member is electrically coupled to the first control electrode pin through a lead, and the third pad is electrically coupled to the first pad.
Clause 17. The semiconductor device according to any of clauses 14 to 16, further comprising a first electrode pin and a second electrode pin, wherein the first electrode pin is electrically coupled to the first pad, and the second electrode pin is electrically coupled to the second pad.
Clause 18. The semiconductor device according to any of clauses 14 to 16, wherein the first chip support member is arranged at a first side of the second chip support member, an on-state current of the first transistor is greater than an on-state current of the second transistor, and a turn-on speed of the first transistor is greater than a turn-on speed of the second transistor.
Clause 19. The semiconductor device according to any of clauses 14 to 16, wherein the first transistor is an FET made of GaN, and the second transistor is an MOSFET made of Si.
Clause 20. The semiconductor device according to any of clauses 3 to 19, wherein the first chip support member and the second chip support member are arranged on a same substrate, and a second distance between the second chip support member and the substrate is greater than a first distance between the first chip support member and the substrate.
Clause 21. The semiconductor device according to clause 20, wherein the second electrode of the second transistor is electrically coupled to the second terminal of the first transistor though a lead;
the lead comprises a first lead portion, a second lead portion and a third lead portion;
a first end of the first lead portion is electrically coupled to the second electrode of the second transistor, a second end of the first lead portion is electrically coupled to a first end of the second lead portion, a second end of the second lead portion is electrically coupled to a first end of the third lead portion, and a second end of the third lead portion is electrically coupled to the second terminal of the first transistor; and
the second upper surface of the second chip support member is perpendicular to the first lead portion, and the first upper surface of the first chip support member is not perpendicular to the third lead portion.
Clause 22. The semiconductor device according to clause 2, further comprising a chip support member, a first semiconductor chip, a second semiconductor chip, a first control electrode pin and a second control electrode pin,
wherein the first transistor is formed on the first semiconductor chip, and the second transistor is formed on the second semiconductor chip;
at least a part of the chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad and a first pad are formed on the first surface of the first semiconductor chip, the first back surface is electrically coupled to the first terminal of the first transistor, the first control electrode pad is electrically coupled to the control electrode of the first transistor and the first control electrode pin respectively, and the first pad is electrically coupled to the second terminal of the first transistor;
a second control electrode pad, at least one second pad and at least one third pad are formed on the first surface of the second semiconductor chip, the second control electrode pad is electrically coupled to the control electrode of the second transistor and the second control electrode pin respectively, the second electrode of the second transistor is electrically coupled to the second pad, and the first electrode of the second transistor is electrically coupled to the third pad;
the chip support member is provided with an upper surface, the first semiconductor chip is supported on the upper surface of the chip support member, and the first back surface of the first semiconductor chip faces the upper surface and is electrically coupled to the chip support member; and
the second semiconductor chip is supported on the upper surface of the chip support member, and the second back surface of the second semiconductor chip faces the upper surface.
Clause 23. The semiconductor device according to clause 22, wherein the third pad is electrically coupled to the first control electrode pin through a lead, and the second pad is electrically coupled to the first pad.
Clause 24. The semiconductor device according to clause 22, wherein the third pad is electrically coupled to the first control electrode pad through a lead, and the second pad is electrically coupled to the first pad.
Clause 25. The semiconductor device according to any of clauses 22 to 24, further comprising a first electrode pin and a second electrode pin, wherein the first electrode pin is electrically coupled to the first pad, and the second electrode pin is electrically coupled to the chip support member.
Clause 26. The semiconductor device according to any of clauses 22 to 24, wherein the first semiconductor chip is arranged at a first side of the second semiconductor chip, and an on-state current of the first transistor is greater than an on-state current of the second transistor.
Clause 27. The semiconductor device according to any of clauses 22 to 24, wherein the first transistor is an MOSFET made of SiC, and the second transistor is an FET made of GaN.
Clause 28. The semiconductor device according to any of clauses 22 to 27, wherein a fourth distance between the first semiconductor chip and the chip support member is greater than a third distance between the first semiconductor chip and the chip support member.
Clause 29. The semiconductor device according to clause 28, wherein the second electrode of the second transistor is electrically coupled to the second terminal of the first transistor through a lead;
the lead comprises a first lead portion, a second lead portion and a third lead portion;
a first end of the first lead portion is electrically coupled to the second electrode of the second transistor, a second end of the first lead portion is electrically coupled to a first end of the second lead portion, a second end of the second lead portion is electrically coupled to a first end of the third lead portion, and a second end of the third lead portion is electrically coupled to the second terminal of the first transistor; and
the second surface of the second semiconductor chip is perpendicular to the first lead portion, and the first surface of the first semiconductor portion is not perpendicular to the third lead portion.
Clause 30. A semiconductor device, comprising an encapsulation body, a first transistor and a capacitor,
wherein the first transistor comprises a control electrode, a first terminal and a second terminal, and the capacitor comprises a first capacitor electrode and a second capacitor electrode;
the first transistor is configured to allow a current to flow from the first terminal to the second terminal under the control of a potential at the control electrode of the first transistor;
the first capacitor electrode is electrically coupled to the control electrode of the first transistor, and the second capacitor electrode is electrically coupled to the second terminal of the first transistor; and
the first transistor and the capacitor are encapsulated by the same encapsulation body, and the control electrode of the first transistor is electrically coupled to a first control electrode pin.
Clause 31. The semiconductor device according to clause 30, wherein the first transistor is an N-type transistor, the first terminal is a first electrode, the first electrode is a drain electrode, the second terminal is a second electrode, and the second electrode is a source electrode; or
the first transistor is a P-type transistor, the first terminal is a first electrode, the first electrode is a source electrode, the second terminal is a second electrode, and the second electrode is a drain electrode.
Clause 32. The semiconductor device according to clause 31, further comprising a chip support member, a first semiconductor chip, a second semiconductor chip and a first control electrode pin,
wherein the first transistor is formed on the first semiconductor chip and the capacitor is formed on the second semiconductor chip;
at least a part of the chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad and a first pad are formed on the first surface of the first semiconductor chip, the first back surface is electrically coupled to the first terminal of the first transistor, the first control electrode pad is electrically coupled to the control electrode of the first transistor and the first control electrode pin respectively, and the first pad is electrically coupled to the second terminal of the first transistor;
a first electrode pad and a second electrode pad are formed on the first surface of the second semiconductor chip, the first electrode pad is electrically coupled to the first capacitor electrode, and the second electrode pad is electrically coupled to the second capacitor electrode;
the chip support member is provided with an upper surface, the first semiconductor chip is supported on the upper surface of the chip support member, and the first back surface of the first semiconductor chip faces the upper surface and is electrically coupled to the chip support member;
the second semiconductor chip is supported on the upper surface of the chip support member, and the second back surface of the second semiconductor chip faces the upper surface; and
the first electrode pad is electrically coupled to the first control electrode pin or the first control electrode pad, and the second electrode pad is electrically coupled to the first pad.
Clause 33. The semiconductor device according to clause 32, further comprising a first electrode pin and a second electrode pin, wherein the first electrode pin is electrically coupled to the first pad, and the second electrode pin is electrically coupled to the chip support member.

What is claimed is:

1. A semiconductor device, comprising an encapsulation body, a first transistor and a second transistor,
wherein the first transistor comprises a control electrode, a first terminal and a second terminal;
the first transistor is configured to allow a current to flow from the first terminal to the second terminal under the control of a potential at the control electrode of the first transistor;
a first electrode of the second transistor is electrically coupled to the control electrode of the first transistor, and a second electrode of the second transistor is electrically coupled to the second terminal of the first transistor; and
the first transistor and the second transistor are encapsulated by the same encapsulation body, the control electrode of the first transistor is electrically coupled to a first control electrode pin, and a control electrode of the second transistor is electrically coupled to a second control electrode pin.

2. The semiconductor device according to claim 1, wherein the first transistor is an N-type transistor, the first terminal is a first electrode, the first electrode is a drain electrode, the second terminal is a second electrode, and the second electrode is a source electrode; or
the first transistor is a P-type transistor, the first terminal is a first electrode, the first electrode is a source electrode, the second terminal is a second electrode, and the second electrode is a drain electrode.

3. The semiconductor device according to claim 2, further comprising a first chip support member, a second chip support member, a first semiconductor chip, a second semiconductor chip, a first control electrode pin and a second control electrode pin,
wherein the first chip support member is insulated from the second chip support member;
the first transistor is formed on the first semiconductor chip, and the second transistor is formed on the second semiconductor chip;
at least a part of the first chip support member, at least a part of the second chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad and a first pad are formed on the first surface of the first semiconductor chip, and the first back surface is electrically coupled to the first terminal of the first transistor;
the first control electrode pad is electrically coupled to the control electrode of the first transistor and the first control electrode pad respectively, and the first pad is electrically coupled to the second terminal of the first transistor;
a second control electrode pad and a second pad are formed on the first surface of the second semiconductor chip, and the second back surface is electrically coupled to the first electrode of the second transistor;
the second control electrode pad is electrically coupled to the control electrode of the second transistor and the second control electrode pin respectively, and the second electrode of the second transistor is electrically coupled to the second pad;
the first chip support member is provided with a first upper surface, the first semiconductor chip is supported on the first upper surface of the first chip support member, and the first back surface of the first semiconductor chip faces the first upper surface and is electrically coupled to the first chip support member; and
the second chip support member is provided with a second upper surface, the second semiconductor chip is supported on the second upper surface of the second chip support member, and the second back surface of the second semiconductor chip faces the second upper surface and is electrically coupled to the second chip support member.

4. The semiconductor device according to claim 3, wherein the second chip support member is electrically coupled to the first control electrode pad through a lead, and the second pad is electrically coupled to the first pad.

5. The semiconductor device according to claim 3, wherein the second chip support member is electrically coupled to the first control electrode pin through a lead, and the second pad is electrically coupled to the first pad.

6. The semiconductor device according to claim 3, further comprising a first electrode pin and a second electrode pin, wherein the first electrode pin is electrically coupled to the first pad, and the second electrode pin is electrically coupled to the first chip support member.

7. The semiconductor device according to claim 3, wherein the first chip support member is arranged at a first side of the second chip support member, an on-state current of the first transistor is greater than an on-state current of the second transistor, and a turn-on speed of the first transistor is greater than a turn-on speed of the second transistor.

8. The semiconductor device according to claim 2, further comprising a first chip support member, a second chip support member, a first semiconductor chip, a second semiconductor chip, a first control electrode pin and a second control electrode pin,
wherein at least a part of the first chip support member, at least a part of the second chip support member, the first semiconductor chip and the second semiconductor chip are encapsulated by the same encapsulation body;
the first transistor is formed on the first semiconductor chip, and the second transistor is formed on the second semiconductor chip;
the first semiconductor chip is provided with a first surface and a first back surface opposite to the first surface, and the second semiconductor chip is provide with a second surface and a second back surface opposite to the second surface;
a first control electrode pad and a first pad are formed on the first surface of the first semiconductor chip, and the first back surface is electrically coupled to the first terminal of the first transistor;
the first control electrode pad is electrically coupled to the control electrode of the first transistor and the first control electrode pin respectively, and the first pad is electrically coupled to the second terminal of the first transistor;
a second control electrode pad and a second pad are formed on the first surface of the second semiconductor chip, and the second back surface is electrically coupled to the first electrode of the second transistor;
the second control electrode pad is electrically coupled to the control electrode of the second transistor and a second control electrode pin respectively, and the second electrode of the second transistor is electrically coupled to the second pad;
the first chip support member is provided with a first upper surface, the first semiconductor chip is supported on the first upper surface of the first chip support member, and the first back surface of the first semiconductor chip faces the first upper surface and is electrically coupled to the first chip support member;
the second chip support member is provided with a second upper surface and a second lower surface opposite to the second upper surface, the second chip support member is supported on the first upper surface of the first chip support member, the second chip support member is insulated from the first chip support member, and the second lower surface of the second chip support member faces the first upper surface; and
the second semiconductor chip is supported on the second upper surface of the second chip support member, and the second back surface of the second semiconductor chip faces the second upper surface and is electrically coupled to the second chip support member.

9. The semiconductor device according to claim 8, wherein the second chip support member is electrically coupled to the first control electrode pad through a lead, and the second pad is electrically coupled to the first pad.

10. The semiconductor device according to claim 8, wherein the second chip support member is electrically coupled to the first control electrode pin through a lead, and the second pad is electrically coupled to the first pad.

11. The semiconductor device according to claim 2, further comprising a first chip support member, a second chip support member, a first semiconductor chip, a second semiconductor chip, a first control electrode pin and a second control electrode pin,
wherein the first chip support member is insulated from the second chip support member; the first transistor is formed on the first semiconductor chip, and the second transistor is formed on the second semiconductor chip;
at least a part of the first chip support member, at least a part of the second chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad, at least one first pad and at least one second pad are formed on the first surface of the first semiconductor chip, the first control electrode pad is electrically coupled to the control electrode of the first transistor and the first control electrode pin respectively, the first pad is electrically coupled to the second terminal of the first transistor, and the second pad is electrically coupled to the first terminal of the first transistor;
a second control electrode pad and a third pad are formed on the first surface of the second semiconductor chip, the second back surface is electrically coupled to the first electrode of the second transistor, the second control electrode pad is electrically coupled to the control electrode of the second transistor and the second control electrode pin respectively, and the second electrode of the second transistor is electrically coupled to the third pad;
the first chip support member is provided with a first upper surface, the first semiconductor chip is supported on the first upper surface of the first chip support member, and the first back surface of the first semiconductor chip faces the first upper surface; and
the second chip support member is provided with a second upper surface, the second semiconductor chip is supported on the second upper surface of the second chip support member, and the second back surface of the second semiconductor chip faces the second upper surface and is electrically coupled to the second chip support member.

12. The semiconductor device according to claim 11, wherein the second chip support member is electrically coupled to the first control electrode pad through a lead, and the third pad is electrically coupled to the first pad.

13. The semiconductor device according to claim 11, wherein the second chip support member is electrically coupled to the first control electrode pin through a lead, and the third pad is electrically coupled to the first pad.

14. The semiconductor device according to claim 2, further comprising a chip support member, a first semiconductor chip, a second semiconductor chip, a first control electrode pin and a second control electrode pin,
wherein the first transistor is formed on the first semiconductor chip, and the second transistor is formed on the second semiconductor chip;
at least a part of the chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad and a first pad are formed on the first surface of the first semiconductor chip, the first back surface is electrically coupled to the first terminal of the first transistor, the first control electrode pad is electrically coupled to the control electrode of the first transistor and the first control electrode pin respectively, and the first pad is electrically coupled to the second terminal of the first transistor;
a second control electrode pad, at least one second pad and at least one third pad are formed on the first surface of the second semiconductor chip, the second control electrode pad is electrically coupled to the control electrode of the second transistor and the second control electrode pin respectively, the second electrode of the second transistor is electrically coupled to the second pad, and the first electrode of the second transistor is electrically coupled to the third pad;
the chip support member is provided with an upper surface, the first semiconductor chip is supported on the upper surface of the chip support member, and the first back surface of the first semiconductor chip faces the upper surface and is electrically coupled to the chip support member; and
the second semiconductor chip is supported on the upper surface of the chip support member, and the second back surface of the second semiconductor chip faces the upper surface.

15. The semiconductor device according to claim 14, wherein the third pad is electrically coupled to the first control electrode pin through a lead, and the second pad is electrically coupled to the first pad.

16. The semiconductor device according to claim 14, wherein the third pad is electrically coupled to the first control electrode pad through a lead, and the second pad is electrically coupled to the first pad.

17. A semiconductor device, comprising an encapsulation body, a first transistor and a capacitor,
wherein the first transistor comprises a control electrode, a first terminal and a second terminal, and the capacitor comprises a first capacitor electrode and a second capacitor electrode;
the first transistor is configured to allow a current to flow from the first terminal to the second terminal under the control of a potential at the control electrode of the first transistor;
the first capacitor electrode is electrically coupled to the control electrode of the first transistor, and the second capacitor electrode is electrically coupled to the second terminal of the first transistor; and
the first transistor and the capacitor are encapsulated by the same encapsulation body, and the control electrode of the first transistor is electrically coupled to a first control electrode pin.

18. The semiconductor device according to claim 17, wherein the first transistor is an N-type transistor, the first terminal is a first electrode, the first electrode is a drain electrode, the second terminal is a second electrode, and the second electrode is a source electrode; or
the first transistor is a P-type transistor, the first terminal is a first electrode, the first electrode is a source electrode, the second terminal is a second electrode, and the second electrode is a drain electrode.

19. The semiconductor device according to claim 18, further comprising a chip support member, a first semiconductor chip, a second semiconductor chip and a first control electrode pin,
wherein the first transistor is formed on the first semiconductor chip and the capacitor is formed on the second semiconductor chip;
at least a part of the chip support member, the first semiconductor chip and the second semiconductor chip are encapsulated by the same encapsulation body;
the first semiconductor chip is provided with a first surface and a first back surface opposite to the first surface, and the second semiconductor chip is provided with a second surface and a second back surface opposite to the second surface;
a first control electrode pad and a first pad are formed on the first surface of the first semiconductor chip, the first back surface is electrically coupled to the first terminal of the first transistor, the first control electrode pad is electrically coupled to the control electrode of the first transistor and the first control electrode pin respectively, and the first pad is electrically coupled to the second terminal of the first transistor;
a first electrode pad and a second electrode pad are formed on the first surface of the second semiconductor chip, the first electrode pad is electrically coupled to the first capacitor electrode, and the second electrode pad is electrically coupled to the second capacitor electrode;
the chip support member is provided with an upper surface, the first semiconductor chip is supported on the upper surface of the chip support member, and the first back surface of the first semiconductor chip faces the upper surface and is electrically coupled to the chip support member;
the second semiconductor chip is supported on the upper surface of the chip support member, and the second back surface of the second semiconductor chip faces the upper surface; and
the first electrode pad is electrically coupled to the first control electrode pin or the first control electrode pad, and the second electrode pad is electrically coupled to the first pad.

20. The semiconductor device according to claim 19, further comprising a first electrode pin and a second electrode pin, wherein the first electrode pin is electrically coupled to the first pad, and the second electrode pin is electrically coupled to the chip support member.
